(19) United States
(12) Patent Application Publication
(10) Pub. No.: US 2025/0165341 A1
(43) Pub. Date: May 22, 2025

(54) NONVOLATILE MEMORY DEVICE, OPERATING METHOD OF NONVOLATILE MEMORY DEVICE, AND OPERATING METHOD OF STORAGE DEVICE

(71) Applicant: SAMSUNG ELECTRONICS CO., LTD., Suwon-si (KR)

(72) Inventors: Seungjun OH, Suwon-si (KR); Kyungduk LEE, Suwon-si (KR); Sangsoon KIM, Suwon-si (KR)

(73) Assignee: SAMSUNG ELECTRONICS CO., LTD., Suwon-si (KR)

(21) Appl. No.: 18/952,294

(22) Filed: Nov. 19, 2024

(30) Foreign Application Priority Data
Nov. 22, 2023 (KR) 10-2023-0163696

(51) Int. Cl. G06F 11/10; G11C 16/04; G11C 16/10

(52) U.S. Cl. CPC G06F 11/1044; G11C 16/0483; G11C 16/10

(57) ABSTRACT

An operating method of a storage device including a nonvolatile memory device and a storage controller includes transmitting, by the storage controller, a set-feature command including error detection activation information to the nonvolatile memory device, transmitting, by the storage controller, a program command and write data to the nonvolatile memory device, performing, by the nonvolatile memory device, an error detection operation on the write data of a page buffer circuit before programming the write data to memory cells, in response to the program command, transmitting, by the nonvolatile memory device, the write data as error data to the storage controller when an error is detected in the write data, and programming, by the nonvolatile memory device, the write data to the memory cells when an error is not detected in the write data.

### CROSS-REFERENCE TO RELATED APPLICATION

This application is based on and claims priority under 35 U.S.C. § 119 to Korean Patent Application No. 10-2023-0163696, filed on Nov. 22, 2023, in the Korean Intellectual Property Office, the disclosure of which is incorporated by reference herein in its entirety.

### BACKGROUND

### 1. Field

The inventive concept relates to a semiconductor memory, and more particularly, to a nonvolatile memory device, an operating method of the nonvolatile memory device, and an operating method of a storage device.

### 2. Description of Related Art

Semiconductor memory devices are classified into volatile memory devices and nonvolatile memory devices. Volatile memory devices may include, but is not limited to, static random-access memory (SRAM) and dynamic random-access memory (DRAM), in which stored data is lost when power supply to the memory is cut off. Nonvolatile memory devices may include, but is not limited to, a flash memory device, phase-change random-access memory (PRAM), magnetoresistive random-access memory (MRAM), resistive random-access memory (RRAM), and ferroelectric random-access memory (FRAM), in which, stored data is retained even when power supply to the memory is cut off.

Recently, as nonvolatile memory devices are required to have high capacity and miniaturization, three-dimensional (3D) memory devices in which a memory cell array and a peripheral circuit are vertically located have been developed. Moreover, in order to increase the capacity of nonvolatile memory devices, an increasing number of word lines stacked on a substrate is provided. With the development of semiconductor processes, as the number of steps of memory cells increases, in other words, as the number of word lines that are stacked increases, the length of a metal line between a peripheral circuit and a memory cell increases. As the length of the metal line between the peripheral circuit and the memory cell increases, the risk of a metal line resistance error increases.

### SUMMARY

One or more aspect of the inventive concept provides a nonvolatile memory device with improved reliability, an operating method of the nonvolatile memory device, and an operating method of a storage device.

According to an aspect of the disclosure, there is provided an operating method of a storage device including a nonvolatile memory device and a storage controller, the operating method including: transmitting, by the storage controller, error detection activation information to the nonvolatile memory device; transmitting, by the storage controller, a program command and write data to the nonvolatile memory device; performing, by the nonvolatile memory device, an error detection operation on the write data in a page buffer circuit based on the error detection activation information; transmitting, by the nonvolatile memory device, the write data as error data to the storage controller based on an error being detected in the write data; and programming, by the nonvolatile memory device, the write data to memory cells in the nonvolatile memory device based on an error not being detected in the write data.

According to another aspect of the disclosure, there is provided an operating method of a nonvolatile memory device, the operating method including: receiving error detection activation information from a storage controller; receiving a program command and write data from the storage controller; performing, based on error detection activation information, an error detection operation by detecting whether a same pattern repeats in the write data of a page buffer circuit; based on an error being detected in the write data, transmitting the write data as error data to the storage controller; and based on an error being not detected in the write data, programming the write data to memory cells in nonvolatile memory device.

According to an aspect of the disclosure, there is provided a nonvolatile memory device including: a memory cell array comprising a plurality of memory cells; an input/output circuit configured to receive write data from a storage controller; a page buffer circuit connected to the memory cell array and configured to temporarily store the write data from the input/output circuit; and an error detection circuit configured to: receive error detection activation information from the storage controller, perform, based on error detection activation information, an error detection operation by detecting whether a same pattern in the write data repeats before programming the write data to the memory cell array, based on an error being detected in the write data, transmit the write data as error data to the storage controller, and based on an error being not detected in the write data, program the write data to the memory cells.

### BRIEF DESCRIPTION OF DRAWINGS

Embodiments will be more clearly understood from the following detailed description taken in conjunction with the accompanying drawings in which:

FIG. 1 is a block diagram illustrating a storage system, according to an embodiment;

FIG. 2 is a block diagram illustrating a nonvolatile memory device of FIG. 1;

FIG. 3 is a diagram for describing a three-dimensional (3D) vertical (V)-NAND structure applicable to a storage device, according to an embodiment;

FIGS. 4A, 4B and 4C are diagrams for describing an error in write data, according to an embodiment;

FIG. 5 is a flowchart illustrating an operating method of a storage device, according to an embodiment;

FIG. 6 is a flowchart illustrating an operating method of a storage controller, according to an embodiment;

FIG. 7 is a flowchart illustrating an operating method of a nonvolatile memory device, according to an embodiment;

FIG. 8 is a flowchart illustrating operation S330 of FIG. 7 according to an embodiment;

FIGS. 9A and 9B are diagrams for describing an operation of a nonvolatile memory device, according to an embodiment;

FIG. 10 is a flowchart illustrating operation S331 of FIG. 8 according to an embodiment;

FIGS. 11A and 11B are diagrams for describing an operation of a nonvolatile memory device, according to an embodiment;

FIG. 12 is a flowchart illustrating operation S333 of FIG. 8 according to an embodiment;

FIGS. 13 and 14 are diagrams for describing an operation of a nonvolatile memory device, according to an embodiment;

FIG. 15 is a flowchart illustrating operation S330 of FIG. 7 according to another embodiment;

FIG. 16 is a flowchart illustrating an operating method of a storage device, according to an embodiment; and

FIG. 17 is a flowchart illustrating an operating method of a storage device, according to an embodiment.

### DETAILED DESCRIPTION

Hereinafter, embodiments will be described in detail by explaining embodiments with reference to the attached drawings in order to enable one of ordinary skill in the art to easily embody and practice the inventive concept.

The following specific embodiments are provided to assist readers in obtaining a full understanding of methods, devices, and/or systems described herein. However, various changes, modifications, and equivalents of the methods, devices, and/or systems described herein will be clear upon understanding the disclosure of the present application. For example, orders of operations described herein are merely exemplary and the disclosure is not limited to those set forth herein, but rather may be altered as will be clear upon an understanding of the disclosure of the present application, except for operations that must occur in a particular order. In addition, descriptions of features known in the art may be omitted for greater clarity and brevity.

The features described herein may be implemented in different forms and should not be construed as being limited to examples described herein. Rather, the examples described herein have been provided to illustrate only some of many feasible ways of realizing the methods, devices, and/or systems described herein, many feasible ways will be clear upon an understanding of the disclosure of the present application.

The terms used herein are used only to describe various examples and will not be used to limit the disclosure. Unless the context clearly indicates otherwise, the singular form is also intended to include the plural form. The terms “comprising,” “including,” and “having” indicate the presence of recited features, quantities, operations, components, elements, and/or combinations thereof, but do not preclude the presence or addition of one or more other features, quantities, operations, components, elements, and/or combinations thereof.

Unless otherwise defined, all terms used herein, including technical and scientific terms, have the same meanings as those commonly understood by those of ordinary skill in the art to which the disclosure pertains after understanding the disclosure. Unless expressly so defined herein, terms (e.g., terms defined in a general-purpose dictionary) should be interpreted as having a meaning consistent with their meaning in the context of the relevant field and the disclosure, and should not be interpreted ideally or in an overly formalistic manner.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment (e.g., as to what an example or embodiment may include or implement) means that at least one example or embodiment exists where such a feature is included or implemented, while all example embodiments are not limited thereto.

The embodiments of the disclosure are example embodiments, and thus, the disclosure is not limited thereto, and may be realized in various other forms. As is traditional in the field, embodiments may be described and illustrated in terms of blocks, as shown in the drawings, which carry out a described function or functions. These blocks, which may be referred to herein as units or modules or the like, or by names such as device, logic, circuit, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

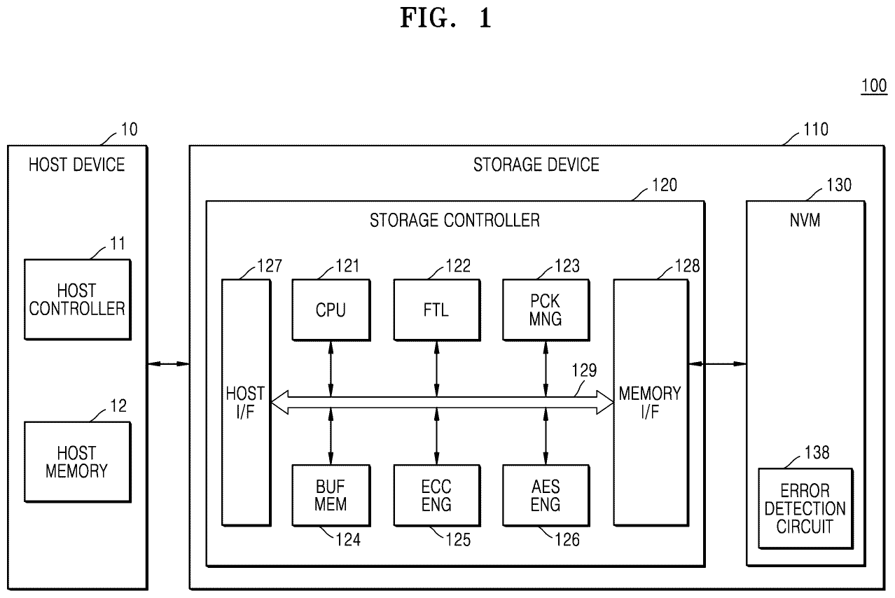

FIG. 1 is a block diagram illustrating a storage system 100, according to an embodiment.

Referring to FIG. 1, the storage system 100 may include a host device 10 and a storage device 110. The storage system 100 may be implemented as an electronic device such as a personal computer (PC), a laptop computer, a mobile phone, a smartphone, a tablet PC, a personal digital assistant (PDA), an enterprise digital assistant (EDA), a digital still camera, a digital video camera, an audio device, a portable multimedia player (PMP), a personal navigation device or portable navigation device (PND), an MP3 player, a handheld game console, or an e-book. However, the disclosure is not limited thereto, and as such, according to another embodiment, the storage system 100 may be implemented as another electronic device or implemented in an electronic device For example, the storage system 100 may be implemented as any of various types of electronic devices, such as a wearable device such as a wristwatch or a head-mounted display (HMD).

The host device 10 may control a data processing operation, for example, a data access operations, such as, but not limited to, a data read operation or a data write operation, on the storage device 110. The host device 10 may refer to a data processing device capable of processing data, such as a central processing unit (CPU), a microprocessor, or an application processor (AP). The host device 10 may execute an operating system (OS) and/or various application programs. For example, the host device 10 may include one or more processors configured to execute one or more instructions or software codes to perform various operations.

For example, the host device 10 may include a host controller 11 and a host memory 12. The host controller 11 may be a device configured to control an overall operation of the host device 10 or allow the host device 10 to control the storage device 110. For example, the host controller 11 may include one or more processors configured to execute one or more instructions or software codes to perform various operations. The host memory 12 may be a buffer memory, a cache memory, or a working memory used in the host device 10.

In an embodiment, the host memory 12 may function as a buffer memory for temporarily storing data to be transmitted to the storage device 110 or data transmitted from the storage device 110. The host device 10 may transmit a request to the storage device 110 and may receive a response from the storage device 110. For example, in a case in which the request is a write request, the request may include write data. For example, in a case in which the request is a read request, the response to the request may include read data.

The storage device 110 may operate under control by the host device 10. The storage device 110 may include a storage controller 120 and a nonvolatile memory device 130. The storage controller 120 may perform various management operations for efficiently using the nonvolatile memory device 130. The nonvolatile memory device 130 may include a plurality of nonvolatile memories.

The storage device 110 may receive a request REQ from the host device 10 and may transmit a response RSP to the host device 10. In an example case in which the request REQ is a write request, the storage controller 120 may control the nonvolatile memory device 130 to write data to the nonvolatile memory device 130 based on the write request from the host device 10. For example, data may be written into the nonvolatile memory device 130 in response to the write request from the host device 10. In an example case in which the request REQ is a read request, the storage controller 120 may control the nonvolatile memory device 130 to read data stored in the nonvolatile memory device 130 based on the read request from the host device 10. For example, data may be read from the nonvolatile memory device 130 in response to the read request from the host device 10.

In a case in which the nonvolatile memory device 130 includes flash memory, the flash memory may include a two-dimensional (2D) NAND memory array or a three-dimensional (3D) vertical NAND (VNAND) memory array. In another example, the storage device 110 may include various other types of nonvolatile memory devices. For example, the storage device 110 may include, but is not limited to, magnetic random-access memory (MRAM), spin-transfer torque MRAM, conductive bridging RAM (CBRAM), ferroelectric RAM (FeRAM), phase RAM (PRAM), resistive RAM, and various other types of memories.

The nonvolatile memory device 130 may include an error detection circuit 138. The error detection circuit 138 may perform an error detection operation. The error detection circuit 138 may perform an error detection operation of detecting whether a same pattern repeats in write data. The error detection circuit 138 may perform an error detection operation before programming the write data to memory cells. The error detection circuit 138 may detect an error in the write data in order to detect a resistance error of a metal line between a memory cell and a peripheral circuit.

The storage controller 120 may include a central processing unit (CPU) 121, a flash translation layer (FTL) 122, a package manager 123, a buffer memory 124, an error correction code (ECC) engine 125, an AES engine 126, a host interface (I/F) circuit 127, a nonvolatile memory interface (I/F) circuit 128, and a bus 129.

The storage controller 120 may further include a working memory into which the FTL 122 is loaded, and a data write operation and a data read operation for the nonvolatile memory device 130 may be controlled based on the CPU 121 executing the FTL 122. For example, in response to executing the FTL 122, the CPU 121 may control or perform a data write operation and a data read operation for the nonvolatile memory device 130.

In an embodiment, the CPU 121 may be implemented as a multi-core processor, for example, a dual-core processor or a quad-core processor. The FTL 122 and the package manager 123 may be loaded into the working memory of the storage controller 120. For example, the working memory may be implemented as a volatile memory such as SRAM or DRAM or a nonvolatile memory such as flash memory or PRAM.

The FTL 122 may perform various functions such as address mapping, wear-leveling, and garbage collection. Address mapping is an operation of changing a logical address received from the host device 10 into a physical address used to actually store data in the nonvolatile memory device 130. Wear-leveling is a technique for preventing excessive deterioration of a specific block by allowing blocks in the nonvolatile memory device 130 to be uniformly used, and may be implemented through, for example, firmware technology that balances erase counts of physical blocks. Garbage collection is a technique for securing usable capacity in the nonvolatile memory device 130 through a method of copying valid data of a block to a new block and then erasing an existing block.

The buffer memory 124 may be configured to temporarily store write data received from the host device 10 or data read received from the nonvolatile memory device 130, under control by the storage controller 120. The following description illustrates an example case in which the buffer memory 124 is SRAM. However, the inventive concept is not limited thereto, and as such, according to another embodiment, the buffer memory 124 may include, but is not limited to, a high-speed random-access memory such as DRAM or synchronous DRAM (SDRAM). In another embodiment, the buffer memory 124 may include a nonvolatile memory such as read-only memory (ROM), programmable ROM (PROM), electrically programmable ROM (EPROM), electrically erasable and programmable ROM (EEPROM), a flash memory device, PRAM, MRAM, RRAM, FRAM, or thyristor RAM (TRAM).

The package manager 123 may generate a packet according to a protocol of an interface with the host device 10 or may parse a variety of information from a packet received from the host device 10. The protocol may be predefined or predetermined. For example, the protocol may be any one of various protocols for establishing an communication between the host device 10 and the storage device 110. The buffer memory 124 may temporarily store data to be written to the nonvolatile memory device 130 or data to be read from the nonvolatile memory device 130. The buffer memory 124 may be an element provided in the storage controller 120, but may be located outside the storage controller 120.

The ECC engine 125 may perform an error detection and correction function on read data obtained from the nonvolatile memory device 130. For example, the ECC engine 125 may generate parity bits for write data to be written to the nonvolatile memory device 130, and the generated parity bits may be stored in the nonvolatile memory device 130 together with the write data. In a case in which data is read from the nonvolatile memory device 130, the ECC engine 125 may correct an error of read data by using the parity bits read from the nonvolatile memory device 130 together with the read data and may output the read data with the error corrected.

In an embodiment, the ECC engine 125 may correct an error by using coded modulation, which may include, but is not limited to, soft decoding, low density parity check (LDPC) code, BCH code, turbo code, Reed-Solomon code, convolution code, recursive systematic code (RSC), trellis-coded modulation (TCM), or block coded modulation (BCM), or various other methods.

In an embodiment, the ECC engine 125 may perform an error correction operation. The ECC engine 125 may receive error data from the nonvolatile memory device 130 and may perform an error correction operation on the error data. For example, the error data may refer to data in which an error is detected through an error detection operation performed by the nonvolatile memory device 130 before a program operation is performed. The ECC engine 125 may detect and correct an error in the error data. In an embodiment, the ECC engine 125 may determine whether an uncorrectable error correction code (UECC) has occurred. The acronym “UECC” may refer to a state including an error that is not corrected by the ECC engine 125. For example, the ECC engine 125 may detect an error in the error data and may further determine that the detected error is not corrected by the ECC engine 125.

In an embodiment, the ECC engine 125 may transmit state information of the error data to the nonvolatile memory interface circuit 128. The ECC engine 125 may transmit state information indicating whether the error data is corrected to the nonvolatile memory interface circuit 128. In a case in which the error in the error data is corrected, the ECC engine 125 may transmit state information indicating a corrected state to the nonvolatile memory interface circuit 128. In a case in which the error in the error data is not corrected, the ECC engine 125 may transmit state information indicating an uncorrected state to the nonvolatile memory interface circuit 128.

The AES engine 126 may perform at least one of an encryption operation and a decryption operation on data input to the storage controller 120. For example, the AES engine 126 may perform the encryption operation or the decryption operation by using a symmetric-key algorithm.

The host interface circuit 127 may transmit a packet to the host device 10 or receive a packet from the host device 10. A packet transmitted from the host device 10 to the host interface circuit 127 may include a command, a request RQ, or data to be written to the nonvolatile memory device 130, and a packet transmitted from the host interface circuit 127 to the host device 10 may include a response to a command or data read from the nonvolatile memory device 130.

The nonvolatile memory interface circuit 128 may transmit data to be written to the nonvolatile memory device 130 to the nonvolatile memory device 130 or may receive data to be read from the nonvolatile memory device 130. The nonvolatile memory interface circuit 128 may be implemented to comply with a standard protocol such as Toggle or open NAND flash interface (ONFI).

In an embodiment, the nonvolatile memory interface circuit 128 may transmit a set-feature command to the nonvolatile memory device 130. The nonvolatile memory interface circuit 128 may transmit a set-feature command to activate or deactivate an error detection operation of the nonvolatile memory device 130. The nonvolatile memory interface circuit 128 may transmit a set-feature command including error detection activation information to the nonvolatile memory device 130 so that the nonvolatile memory device 130 performs an error detection operation before a program operation. The nonvolatile memory interface circuit 128 may transmit a set-feature command including an error detection deactivation information to the nonvolatile memory device 130 to prevent the nonvolatile memory device 130 from performing an error detection operation before a program operation.

In an embodiment, the nonvolatile memory interface circuit 128 may receive error data from the nonvolatile memory device 130. For example, after the nonvolatile memory interface circuit 128 transmits a set-feature command including error detection activation information and a program command to the nonvolatile memory device 130, the nonvolatile memory interface circuit 128 may receive error data from the nonvolatile memory device 130. For example, the nonvolatile memory interface circuit 128 may receive error data from the nonvolatile memory device 130 based on the set-feature command including the error detection activation information and the program command. The nonvolatile memory interface circuit 128 may transmit the error data to the ECC engine 125.

In an embodiment, the nonvolatile memory interface circuit 128 may receive state information of the error data from the ECC engine 125. In a case in which the nonvolatile memory interface circuit 128 receives state information indicating a corrected state, the nonvolatile memory interface circuit 128 may transmit a resume command RESUME CMD to the nonvolatile memory device 130. In a case in which the nonvolatile memory interface circuit 128 receives state information indicating an uncorrected state, the nonvolatile memory interface circuit 128 may perform an input/output adjustment operation.

In an embodiment, the nonvolatile memory interface circuit 128 may perform an input/output adjustment operation with respect to the nonvolatile memory device 130. The nonvolatile memory interface circuit 128 may adjust a voltage input to the nonvolatile memory device 130 to reduce a resistance error of a metal line between a peripheral circuit and a memory cell of the nonvolatile memory device 130. For example, the input/output adjustment operation may refer to an operation of adjusting a power supply voltage VCC or an input/output voltage VCCQ input to the nonvolatile memory device 130. The nonvolatile memory interface circuit 128 may decrease or increase the power supply voltage VCC. The nonvolatile memory interface circuit 128 may decrease or increase the input/output voltage VCCQ. However, the disclosure is not limited thereto, and as such, the input/output adjustment operation corresponding to the nonvolatile memory device 130 may be performed in another manner.

As described above, the nonvolatile memory device 130 of the storage device 110 according to an embodiment may detect a program pattern error by determining whether there is an error in write data before programming the write data. Accordingly, the storage device 110 with improved reliability is provided.

Hereinafter, for convenience of explanation, the terms “error”, “failure”, and “defect” are interchangeably used. These terms may have the same or different meanings according to the context of embodiments, and the meaning of each term will be understood according to the context of embodiments described below.

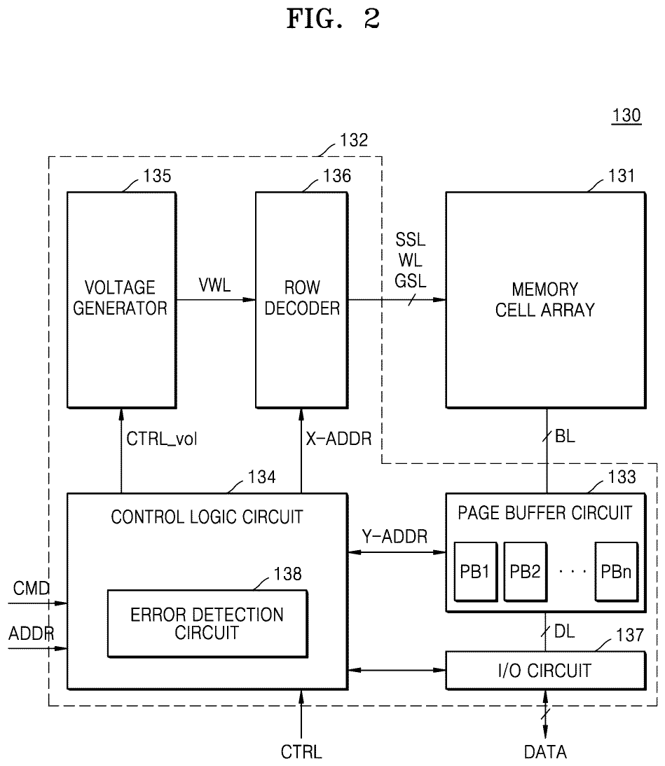

FIG. 2 is a block diagram illustrating a nonvolatile memory device according to an embodiment.

For example, the nonvolatile memory device illustrated in FIG. 2 may be the nonvolatile memory device 130 of FIG. 1. Referring to FIGS. 1 and 2, the nonvolatile memory device 130 may include a memory cell array 131 and a peripheral circuit 132. For convenience of explanation, the following illustration describes an embodiment in which the nonvolatile memory device 130 is a NAND flash memory device, but the inventive concept is not limited thereto, and as such, the nonvolatile memory device 130 may be a different type of memory device, and one or more aspect of the inventive concept described below will be applicable.

The peripheral circuit 132 may include a page buffer circuit 133, a control logic circuit 134, a voltage generator 135, a row decoder 136, and an input/output (I/O) circuit 137. The control logic circuit 134 may include the error detection circuit 138. However, the disclosure is not limited thereto, and as such, according to another embodiment, the nonvolatile memory device 130 may further include a column logic, a pre-decoder, a temperature sensor, a command decoder, and an address decoder. For example, peripheral circuit 132 may include one or more other components, including but not limited to, the column logic, the pre-decoder, the temperature sensor, the command decoder, and the address decoder.

The memory cell array 131 may include a plurality of memory blocks, each of the plurality of memory blocks may include a plurality of cell strings, and each of the plurality of cell strings may include a plurality of memory cells connected in series. The memory cell array 131 may be connected to the page buffer circuit 133 through bit lines BL and may be connected to the row decoder 136 through word lines WL, string selection lines SSL, and ground selection lines GSL.

In an embodiment, each of the plurality of memory blocks may include a plurality of memory cells. Each of the plurality of memory cells may be connected through the word lines WL. Each of the plurality of memory cells may be a single-level cell (SLC) storing 1-bit data or a multi-level cell (MLC) storing at least 2-bit data.

In an embodiment, the memory cell array 131 may include a 3D memory cell array, and the 3D memory cell array may include a plurality of cell strings. Each cell string may include memory cells connected to word lines that are vertically stacked on a substrate. U.S. Pat. Nos. 7,679,133, 8,553,466, 8,654,587, 8,559,235, and U.S. Patent Application Publication No. 2011/0233648 are incorporated by reference herein.

In an embodiment, the memory cell array 131 may include flash memory, and the flash memory may include a 2D NAND memory array or a 3D VNAND memory array. In an embodiment, the memory cell array 131 may include, but is not limited to MRAM, spin-transfer torque MRAM, CBRAM, FeRAM, PRAM, RRAM, and various other types of memories.

In an embodiment, the memory cell array 131 may be formed in a cell area of a semiconductor substrate, and the peripheral circuit 132 may be formed in a peripheral area physically separated from the cell area of the semiconductor substrate. In an embodiment, the peripheral circuit 132 may be formed on the semiconductor substrate, and the memory cell array 131 may be stacked on the peripheral circuit 132. That is, the nonvolatile memory device 130 may have a cell-on-peripheral (COP) structure. However, the inventive concept is not limited thereto, and the nonvolatile memory device 130 may be implemented to have any of various structures.

The page buffer circuit 133 may include a plurality of page buffers PB1 to PBn, and the plurality of page buffers PB1 to PBn may be respectively connected to the memory cells through the plurality of bit lines BL. For example, n may be an integer of 3 or more. The page buffer circuit 133 may select at least one bit line from among the bit lines BL based on a column address Y-ADDR. The page buffer circuit 133 may receive write data from the input/output circuit 137. The page buffer circuit 133 may temporarily store the write data.

The page buffer circuit 133 may operate as a write driver or a sense amplifier according to an operation mode. For example, during a program operation, the page buffer circuit 133 may apply a bit line voltage corresponding to data to be programmed to a selected bit line. In an example, a program operation may refer to a write operation. During a read operation, the page buffer circuit 133 may detect data stored in a memory cell by detecting current or a voltage of a selected bit line.

The control logic circuit 134 may control various operations in the nonvolatile memory device 130. The control logic circuit 134 may output various control signals based on a command CMD and/or an address ADDR. For example, the control logic circuit 134 may output a voltage control signal CTRL_vol, a row address X_ADDR, and a column address Y_ADDR.

The voltage generator 135 may generate various types of voltages for performing program, read, and erase operations based on the voltage control signal CTRL_vol. For example, the voltage generator 135 may generate a program voltage, a read voltage, a program verification voltage, and an erase voltage as a word line voltage VWL.

The row decoder 136 may select least one of the plurality of word lines WL based on the row address X_ADDR and may select one of the plurality of string selection lines SSL. For example, during a program operation, the row decoder 136 may apply the word line voltages VWL to selected word lines during a search operation or a read operation.

The input/output circuit 137 may provide data DATA received from the storage controller 120 to the page buffer circuit 133 through a data line DL or may provide data DATA received through a data line DL to the storage controller 120. For example, the input/output circuit 137 may transmit write data received from the storage controller 120 to the page buffer circuit 133. In an embodiment, in synchronization with a data strobe signal DQS, the input/output circuit 137 may transmit the data DATA to the storage controller 120 and receive the data DATA from the storage controller 120. In an embodiment, information such as the command CMD or the address ADDR shown in FIG. 2 may be received through the input/output circuit 137 and the received information may be provided to each corresponding circuit.

Referring to FIGS. 1 and 2 together, the storage controller 120 may control an operation of the nonvolatile memory device 130. For example, the storage controller 120 may control the nonvolatile memory device 130 by providing a control signal CTRL and a data signal DQ to the nonvolatile memory device 130 through different signal lines or different signal pins.

For example, the storage controller 120 may provide a chip enable signal CE/, a command latch enable signal CLE, an address latch enable signal ALE, a write enable signal WE/, a read enable signal RE/, a data strobe signal DQS, and the data signal DQ to the nonvolatile memory device 130 through different signal pins.

The chip enable signal CE/, the command latch enable signal CLE, the address latch enable signal ALE, the write enable signal WE/, the read enable signal RE/, and the data strobe signal DQS may be included in the control signal CTRL provided from the storage controller 120. The storage controller 120 may provide the control signal CTRL and the data signal DQ to the nonvolatile memory device 130 so that the nonvolatile memory device 130 performs various operations.

The nonvolatile memory device 130 performs a corresponding operation in response to the control signal CTRL and the data signal DQ provided from the storage controller 120. For example, based on the control signal CTRL and the data signal DQ provided from the storage controller 120, the nonvolatile memory device 130 may perform one or more operations corresponding to the control signal CTRL and the data signal DQ. For example, the nonvolatile memory device 130 may receive the data signal DQ including the command CMD and the address ADDR from the storage controller 120 and may provide stored data DATA to the storage controller 120.

The nonvolatile memory device 130 may determine whether a signal provided through the data signal DQ is the command CMD, the address ADDR, or the data DATA based on the control signal CTRL. For example, the nonvolatile memory device 130 may identify a type of the data signal DQ, based on the chip enable signal CE/, the command latch enable signal CLE, the address latch enable signal ALE, the write enable signal WE/, the read enable signal RE/, and the data strobe signal DQS.

The nonvolatile memory device 130 may store data received from the storage controller 120 or may transmit stored data to the storage controller 120 based on various signals from the storage controller 120. In an example case in which the nonvolatile memory device 130 performs a program operation or a read operation under control by the storage controller 120, the nonvolatile memory device 130 may provide a ready/busy signal R/B (or state information) to the storage controller 120. For example, the ready/busy signal R/B may indicate a ready state or a busy state. The storage controller 120 may recognize that the nonvolatile memory device 130 is operating in response to the ready/busy signal R/B. In an example case in which the read/busy signal R/B indicates a busy state, the storage controller 120 may not exchange information (command, address, or data) with the nonvolatile memory device 130.

In an embodiment, the storage controller 120 may transmit a set-feature command or a program command to the nonvolatile memory device 130 through the control signal CTRL and the data signal DQ. The storage controller 120 may receive error data through the control signal CTRL and the data signal DQ.

The nonvolatile memory device 130 may receive the set-feature command or the program command through the control signal CTRL and the data signal DQ. The nonvolatile memory device 130 may transmit the error data to the storage controller 120 through the control signal CTRL and the data signal DQ.

In an embodiment, the control logic circuit 134 may include the error detection circuit 138. The error detection circuit 138 may perform an error detection operation on write data of the page buffer circuit 133 before a program operation is performed. The error detection circuit 138 may detect a pattern abnormality of the write data before the write data is written to the memory cell array 131. The error detection circuit 138 may determine whether a certain pattern repeats in the write data. According to scaling-down of a semiconductor process, the risk of an error occurring due to fine breakage of a metal line between the memory cells of the memory cell array 131 and the peripheral circuit 132 of the nonvolatile memory device 130 increases. Such an error is a type of error occurring in recently developed products and is expected to continue to occur in next-generation products.

In an embodiment, an error due to a metal line defect may intermittently occur when the nonvolatile memory device 130 is powered on/off. For example, in a case in which the nonvolatile memory device 130 changes from power-off to power-on or changes from power-on to power-off, a metal line error may occur between the peripheral circuit 132 and the memory cells.

In general, in a case in which a program failure occurs, the storage controller 120 may handle the error by writing data stored in the buffer memory 124 back to the nonvolatile memory device 130 or writing data received from the host device 10 back to the nonvolatile memory device 130. However, an exceptional program error, rather than an error occurring while data is programmed to the memory cell array 131, may occur. For example, an error due to an input/output problem may occur between the storage controller 120 and the nonvolatile memory device 130. Such an exceptional program error may result in a read failure.

In other words, an error may occur due to an input/output problem. For example, the error may occur due to an input/output problem between the storage controller 120 and the nonvolatile memory device 130. In this case, the storage device 110 may not detect an error during a program operation and may detect the error as a read failure through a read operation on data in which the error has occurred.

An input/output error may be an error occurring equally in all banks of the nonvolatile memory device 130. The input/output error may be estimated as an error in terms of the storage controller 120 or a substrate (e.g., a printed circuit board (PCB)), but may be an error of the nonvolatile memory device 130. For example, from among write errors of the nonvolatile memory device 130, a write error in metadata may occur. Due to the write error in metadata, a read failure of the metadata may occur. In this case, the storage device 110 may enter an unrecognizable or inoperable state, and thus, all data stored in the storage device 110 may be lost. The nonvolatile memory device 130 according to an embodiment may prevent a read failure of metadata in advance by detecting a data error in advance before a program operation.

As described above, the nonvolatile memory device 130 may perform an error detection operation before programming data to a memory cell. Accordingly, the nonvolatile memory device 130 with improved reliability may be provided.

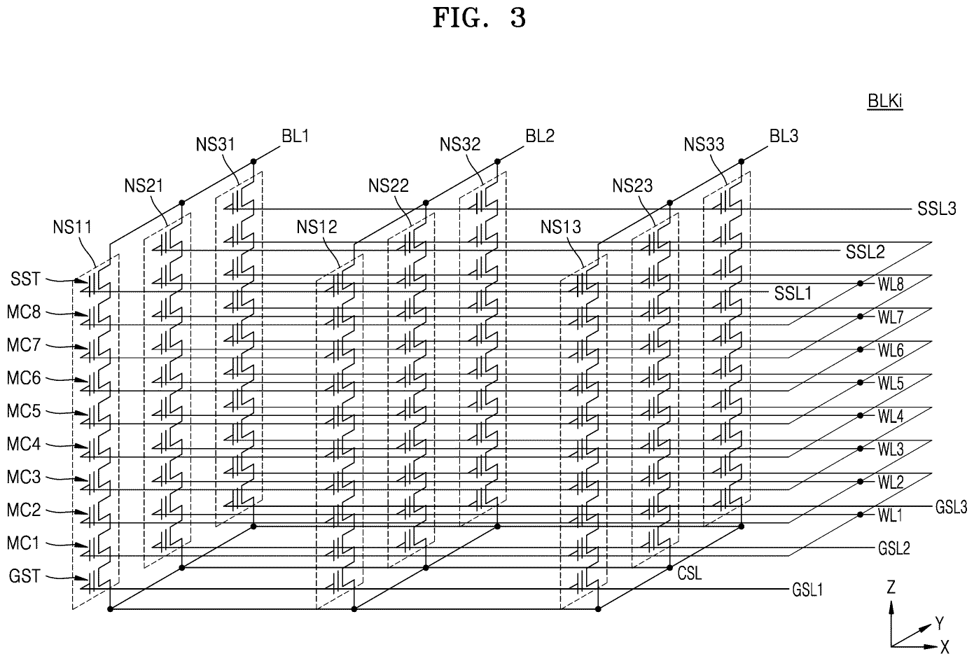

FIG. 3 is a diagram illustrating a 3D V-NAND structure applicable to a storage device, according to an embodiment.

In an example case in which a nonvolatile memory device of a storage device is implemented as a 3D V-NAND type flash memory, each of a plurality of memory blocks constituting a memory cell array may be represented as an equivalent circuit as shown in FIG. 3.

A memory block BLKi of FIG. 3 is a 3D memory block formed in a 3D structure on a substrate. For example, a plurality of memory NAND strings included in the memory block BLKi may be formed in a direction perpendicular to the substrate.

Referring to FIG. 3, the memory block BLKi may include a plurality of memory NAND strings NS11 to NS31 connected between a first bit line BL1 and a common source line CSL, NS12 to NS32 connected between a second bit line BL2 and the common source line CSL, and NS13 to NS33 connected between a third bit line BL3 and the common source line CSL. Each of the plurality of memory NAND strings NS11 to NS33 may include a string selection transistor SST, a plurality of memory cells, e.g., first to eighth memory cells MC1, MC2, . . . , and MC8, and a ground selection transistor GST. Although each of the plurality of memory NAND strings NS11 to NS33 includes eight memory cells e.g., MC1, MC2, . . . , and MC8, in FIG. 3, the inventive concept is not limited thereto.

The string selection transistors SST may be connected corresponding string selection lines SSL1, SSL2, and SSL3. The plurality of memory cells, e.g., MC1, MC2, . . . , and MC8, may be respectively connected to corresponding gate lines GTL1, GTL2, . . . , and GTL8. The gate lines GTL1, GTL2, . . . , and GTL8 may correspond to word lines, and some of the gate lines GTL1, GTL2, . . . , and GTL8 may correspond to dummy word lines. The ground selection transistors GST may be connected to corresponding ground selection lines GSL1, GSL2, and GSL3. The string selection transistors SST may be connected to corresponding first to third bit lines BL1, BL2, and BL3, and the ground selection transistor GST may be connected to the common source line CSL.

Word lines (e.g., WL1) at the same height may be commonly connected, and the ground selection lines GSL1, GSL2, and GSL3 and the string selection lines SSL1, SSL2, and SSL3 may be separated from each other. Although the memory block BLK is connected to eight gate lines GTL1, GTL2, . . . , and GTL8 and three bit lines, that is, the first to third bit lines BL1, BL2, and BL3, in FIG. 3, the inventive concept is not limited thereto.

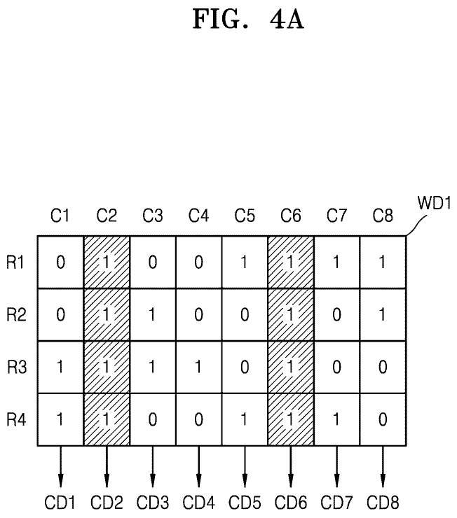

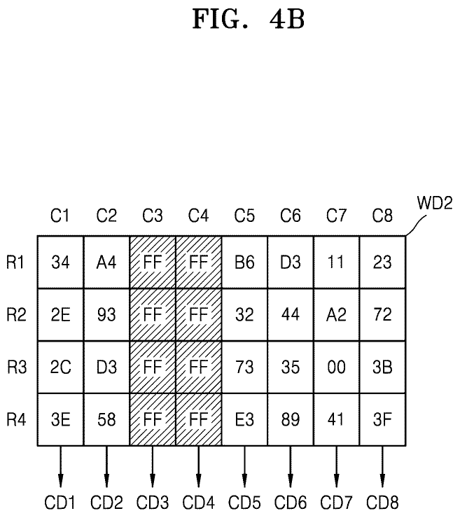

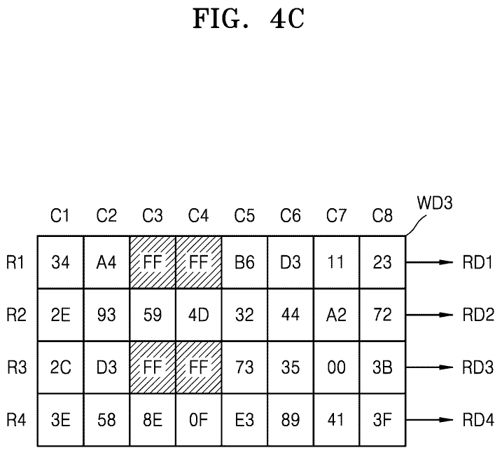

FIGS. 4A, 4B and 4C are diagrams for describing an error in write data, according to an embodiment.

Examples of write data in which an error occurs will be described with reference to FIGS. 4A, 4B and 4C. However, the inventive concept is not limited thereto, and there may be various error patterns and the size of write data may vary according to implementation.

Referring to FIGS. 2, 4A, 4B and 4C, the page buffer circuit 133 may store first write data WD1, second write data WD2 and third write data WD3. The first to third write data WD1, WD2, and WD3 may include an error occurring during an input/output operation before being written to the memory cell array 131. That is, an error may occur while write data is transmitted from the storage controller 120 to the page buffer circuit 133 of the nonvolatile memory device 130.

For example, the first write data WD1 may have a binary format and may be ‘32 bits’. The first write data WD1 may include a plurality of pieces of bit data. The plurality pieces of bit data may be arranged in rows and columns. The first write data WD1 may include ‘4’ rows and ‘8” columns. For example, first column data CD1 in a first column C1 may be ‘0011’, second column data CD2 in a second column C2 may be ‘1111’, third column data CD3 in a third column C3 may be ‘0110’, fourth column data CD4 in a fourth column C4 may be ‘0010’, fifth column data CD5 in a fifth column C5 may be ‘1001’, sixth column data CD6 in a sixth column C6 may be ‘1111’, seventh column data CD7 in a seventh column C7 may be ‘1001’, and eighth column data CD8 in an eight column C8 may be ‘1100’.

An error may occur in the second column data CD2 and the sixth column data CD6 of the first write data WD1. The second column data CD2 of the first write data WD1 may include only a first value (e.g., ‘1’). The sixth column data CD6 of the first write data WD1 may include only the first value (e.g., ‘1’). That is, the first write data WD1 may include an error in which all bits of column data in the second column C2 and the sixth column C6 have the same value.

In an embodiment, the error detection circuit 138 may detect whether a pattern such as the first write data WD1 repeats. The error detection circuit 138 may determine whether there is an error by determining whether all pieces of column data of write data have the same value. For example, the error detection circuit 138 may identify an error based on a determination that all pieces of column data of write data have the same value.

For example, the second write data WD2 may have a hexadecimal format and may be ‘32 bytes’. The second write data WD2 may include a plurality of pieces of byte data. The plurality of pieces of byte data may be arranged in rows and columns. The second write data WD2 may include ‘4’ rows and ‘8’ columns. For example, first column data CD1 in a first column C1 may be ‘34 2E 2C 3E’, second column data CD2 in a second column C2 may be ‘A4 93 D3 58’, third column data CD3 in a third column C3 may be ‘FF FF FF FF’, fourth column data CD4 in a fourth column C4 may be ‘FF FF FF FF’, fifth column data CD5 in a fifth column C5 may be ‘B6 32 73 E3’, sixth column data CD6 in a sixth column C6 may be ‘D3 44 35 89’, seventh column data CD7 in a seventh column C7 may be ‘11 A2 00 41’, and eighth column data CD8 in a eighth column C8 may be ‘23 72 3B 3F’.

The second write data WD2 may have an error in the third column data CD3 and the fourth column data CD4. The third column data CD3 of the second write data WD2 may include only a third value (e.g., ‘FF’). The fourth column data CD4 of the second write data WD2 may include only the third value (e.g., ‘FF’). That is, the second write data WD2 may include an error in which all bytes of column data in the third column C3 and the fourth column C4 have the same value.

In an embodiment, the error detection circuit 138 may detect whether a pattern such as the second write data WD2 repeats. The error detection circuit 138 may determine whether there is an error by determining whether all pieces of column data of write data have the same value. In another embodiment, the error detection circuit 138 may determine whether there is an error by determining whether a plurality of pieces of adjacent column data of write data have the same value.

For example, the third write data WD3 may have a hexadecimal format and may be ‘32 bytes’. The third write data WD3 may include a plurality of pieces of byte data. The plurality of pieces of byte data may be arranged in rows and columns. The third write data WD3 may include ‘4’ rows and ‘8’ columns. For example, first row data RD1 in a first row R1 may be ‘34 A4 FF FF B6 D3 11 23’, second row data RD2 in a second row R2 may be ‘2E 93 59 4D 32 44 A2 72’, third row data RD3 in a third row R3 may be ‘2C D3 FF FF 73 35 00 3B’, and fourth row data RD4 in a fourth row R4 may be ‘3E 58 8E OF E3 89 41 3F’.

The third write data WD3 may have an error in part of the first row data RD1 and part of the third row data RD3. An error may occur in byte data of the first row R1 and the third column C3 of the third write data WD3 and byte data of the first row R1 and the fourth column C4, and an error may occur in byte data of the third row R3 and the third column C3 of the third write data WD3 and byte data of the third row R3 and the fourth column C4. The third write data WD3 may include the same data, such as the third value (e.g., ‘FF’), in units of specific multiples.

In an embodiment, the error detection circuit 138 may detect whether a pattern such as the third write data WD3 repeats. The error detection circuit 138 may determine whether there is an error by determining whether some pieces of row data of write data have the same value. In another embodiment, the error detection circuit 138 may determine whether there is an error by determining whether some pieces of odd (or even, or specific multiple) row data of write data have the same value.

As described above, write data may include errors of various patterns due to an input/output error. The error detection circuit 138 may detect the errors of various patterns.

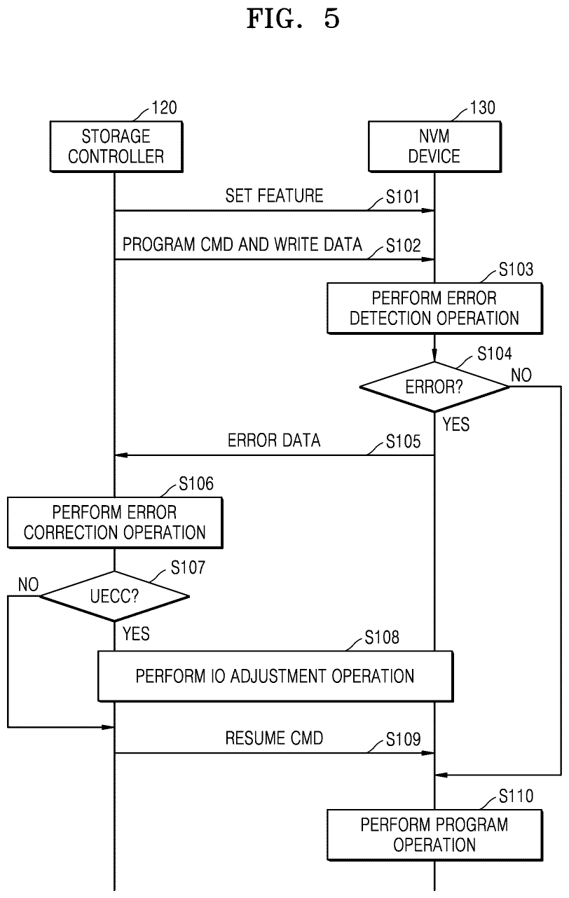

FIG. 5 is a flowchart illustrating an operating method of a storage device, according to an embodiment.

Referring to FIGS. 1 and 5, in operation S101, the storage controller 120 may transmit a set-feature command SET FEATURE to the nonvolatile memory device 130. The set-feature command in operation S101 may be a command for setting whether to perform an error detection operation of the nonvolatile memory device 130. The set-feature command may indicate whether to perform an error detection operation of the nonvolatile memory device 130. The storage controller 120 may transmit a set-feature command including an error detection activation information to the nonvolatile memory device 130.

In operation S102, the storage controller 120 may transmit a program command and write data to the nonvolatile memory device 130. The program command may include an address indicating an area of memory cells storing 1-bit data. For example, the storage controller 120 may store, in an SLC area, data for which high reliability is required. For example, high reliability data may include, but is not limited to, metadata. The storage controller 120 may instruct the nonvolatile memory device 130 to perform an error detection operation on the data for which high reliability is required before a program operation is performed.

In operation S103, the nonvolatile memory device 130 may perform an error detection operation. The nonvolatile memory device 130 may perform an error detection operation based on the set-feature command including the error detection activation information and the program command. The nonvolatile memory device 130 may determine whether there is an error in the write data of the page buffer circuit 133. For example, the nonvolatile memory device 130 may determine whether a same pattern repeats in the write data in the page buffer circuit 133.

In operation S104, the nonvolatile memory device 130 may determine whether the write data includes an error. In a case in which the nonvolatile memory device 130 determines that the write data includes an error, the nonvolatile memory device 130 performs operation S105, and in a case in which the nonvolatile memory device 130 determines that the write data does not include an error, the nonvolatile memory device 130 performs operation S110.

In operation S105, the nonvolatile memory device 130 may transmit error data to the storage controller 120. For example, the nonvolatile memory device 130 may transmit the write data of the page buffer circuit 133 as error data to the storage controller 120. During a program operation that does not perform an error detection operation, the nonvolatile memory device 130 does not transmit data to the storage controller 120. However, in a program operation that performs an error detection operation, in a case in which an error is detected in the write data, the nonvolatile memory device 130 may transmit error data to the storage controller 120.

In operation S106, the storage controller 120 may perform an error correction operation. The storage controller 120 may perform an error correction operation on the error data in response to receiving the error data from the nonvolatile memory device 130. The storage controller 120 may detect and correct the error in the data provided by the nonvolatile memory device 130.

In operation S107, the storage controller 120 may determine whether UECC of the error data occurs. In a case in which the UECC occurs, the storage controller 120 performs operation S108, and in a case in which the UECC does not occur, the storage controller 120 performs operation S109.

In operation S108, the storage controller 120 and the nonvolatile memory device 130 may perform an input/output adjustment operation. For example, in a case in which UECC occurs, the storage controller 120 may adjust voltages input to the nonvolatile memory device 130. That is, in a case in which the error is not corrected, the storage controller 120 may adjust voltages input to the nonvolatile memory device 130. For example, the storage controller 120 may increase or decrease a power supply voltage VCC. The storage controller 120 may increase or decrease an input/output voltage VCCQ. The storage controller 120 may optimize input/output of the nonvolatile memory device 130. Next, the storage controller 120 performs operation S109.

In operation S109, the storage controller 120 may transmit a resume command RESUME CMD to the nonvolatile memory device 130. For example, in a case in which UECC does not occur, the storage controller 120 may transmit a resume command for the program operation. That is, in a case in which the error is corrected, the storage controller 120 may transmit a resume command for the program operation. The storage controller 120 may resume the program operation that has been stopped.

In operation S110, the nonvolatile memory device 130 may perform an program operation. In a case in which no error is detected, the nonvolatile memory device 130 may program the write data to memory cells.

Although FIG. 5 illustrates an operating method of a storage device, the disclosure is not limited thereto, and as such, according to another embodiment, other operations may be performed in addition to the operations illustrated in FIG. 5. According to an embodiment, the order of the operations in the operating method of the storage device is not limited to the illustration in FIG. 5.

As described above, according to an embodiment, the storage device 110 may detect an error in data before programming (or writing) the data to a memory cell. The storage device 110 may reduce an error of the storage device 110 by performing an error detection operation on data for which reliability is required. The data reliability of the storage device 110 may be improved.

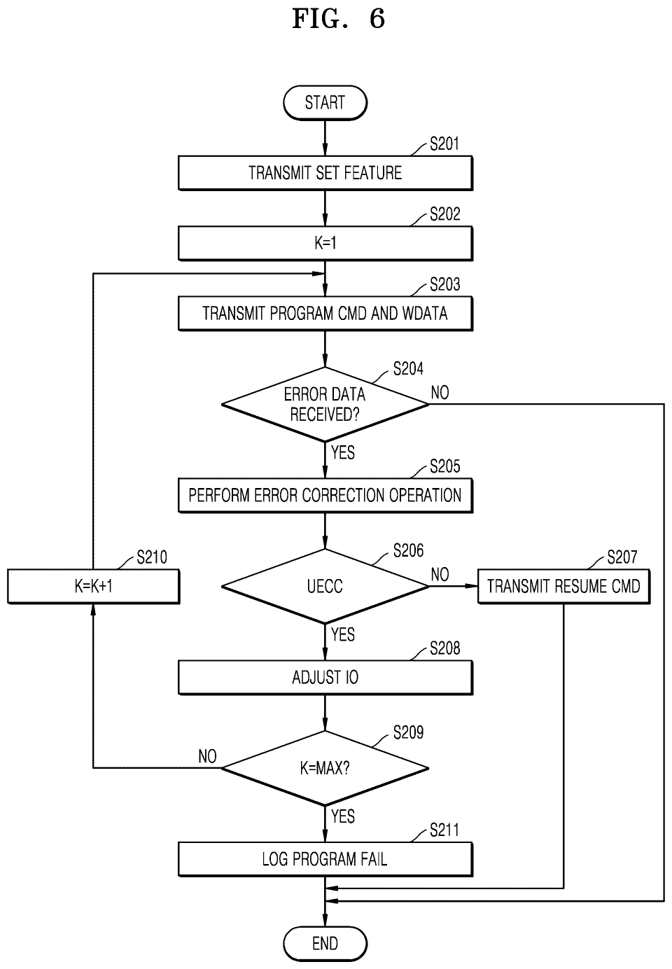

FIG. 6 is a flowchart illustrating an operating method of a storage controller, according to an embodiment.

Referring to FIGS. 1, 2, and 6, in operation S201, the storage controller 120 may transmit a set-feature command. The storage controller 120 may transmit a set-feature command in order to activate error detection. In operation S202, a variable K may be set to 1. For example, the variable K is used to describe an operation of repeatedly transmitting a program command based on an error of the nonvolatile memory device 130. However, the scope of the inventive concept is not limited to the example operation illustrated in FIG. 6.

In operation S203, the storage controller 120 may transmit a program command and write data to the nonvolatile memory device 130. For example, the write data may be metadata for which high reliability is required. The program command may be a program command for writing the write data to an SLC area.

In operation S204, the storage controller 120 may determine whether error data has been received from the nonvolatile memory device 130. For example, in a case in which the nonvolatile memory device 130 detects an error by performing an error detection operation before a program operation, the nonvolatile memory device 130 may transmit error data to the storage controller 120. The storage controller 120 may receive the error data. In a case in which the storage controller 120 receives the error data from the nonvolatile memory device 130, the storage controller 120 performs operation S205, and in a case in which the storage controller 120 does not receive the error data from the nonvolatile memory device 130, the storage controller 120 does not perform the following operations. In a case in which the storage controller 120 does not receive the error data, the storage controller 120 may recognize that an error has not occurred in the write data. In this case, the storage controller 120 may complete the program operation.

In operation S205, the storage controller 120 may perform an error correction operation. The storage controller 120 may perform an error correction operation on the data received from the nonvolatile memory device 130. For example, the ECC engine 125 of the storage controller 120 may perform an error correction operation on the error data received from the nonvolatile memory device 130.

In operation S206, the storage controller 120 may determine whether UECC has occurred. The storage controller 120 may determine whether the error correction operation has failed. In a case in which the error data includes an error exceeding the error correction capability of the ECC engine 125, the storage controller 120 may determine that the error correction operation has failed. In a case in which UECC occurs, the storage controller 120 performs operation S208, and in a case in which UECC does not occur, the storage controller 120 performs operation S207. For example, based on the error being not corrected or being not correctable, the storage controller 120 performs operation S208, and based on the error being corrected, the storage controller 120 performs operation S207.

In operation S207, the storage controller 120 may transmit a resume command. The storage controller 120 may resume the program operation again, because the storage controller 120 may correct the error through the error correction operation.

In operation S208, the storage controller 120 may adjust input/output of the nonvolatile memory device 130. The storage controller 120 may adjust a power supply voltage or an input/output voltage input to the nonvolatile memory device 130 in order to prevent a metal line error.

In operation S209, the storage controller 120 may determine whether the variable K is a maximum value. The maximum value may be a pre-determined value. The maximum value may be selected to be fixed or variable by a designer, a manufacturer, and/or a user. After the input/output adjustment operation is performed, the storage controller 120 may determine whether a program count, which is the number of times a program command is transmitted for the same address, is equal to or greater than a threshold value. In a case in which the variable K is the maximum value, the storage controller 120 performs operation S211, and in a case in which the variable K is not the maximum value, the storage controller 120 performs operation S210.

In operation S210, the storage controller 120 may increase the variable K by 1. Next, the storage controller 120 may perform operation S203. Because the storage controller 120 has failed to correct the error detected by the nonvolatile memory device 130, the storage controller 120 may re-transmit a program command. That is, based on the storage controller 120 determining that the program count is less than the threshold value, the storage controller 120 may re-transmit a program command and write data to the nonvolatile memory device 130. The storage controller 120 may request the nonvolatile memory device 130 to perform an error detection operation and a program operation again so that data with no error is written to the memory cell array 131.

In operation S211, the storage controller 120 may log a program failure. in a case in which an error is detected and the error is not corrected while the storage controller 120 repeatedly performs a program operation as many times as the maximum value, the storage controller 120 may determine a program failure and may store information about the program failure in a memory. For example, based on the storage controller 120 determining that the program count is equal to or greater than the threshold value, the storage controller 120 may determine a program failure and may store information about the program failure. The storage controller 120 may store the information about the program failure in a log page.

As described above, the storage controller 120 may request the nonvolatile memory device 130 to perform an error detection operation, may receive error data from the nonvolatile memory device 130, and may perform an error correction operation on the error data. Also, the storage controller 120 may repeatedly transmit a program command to store data that does not include an error or data that may be corrected in the memory cell array 131.

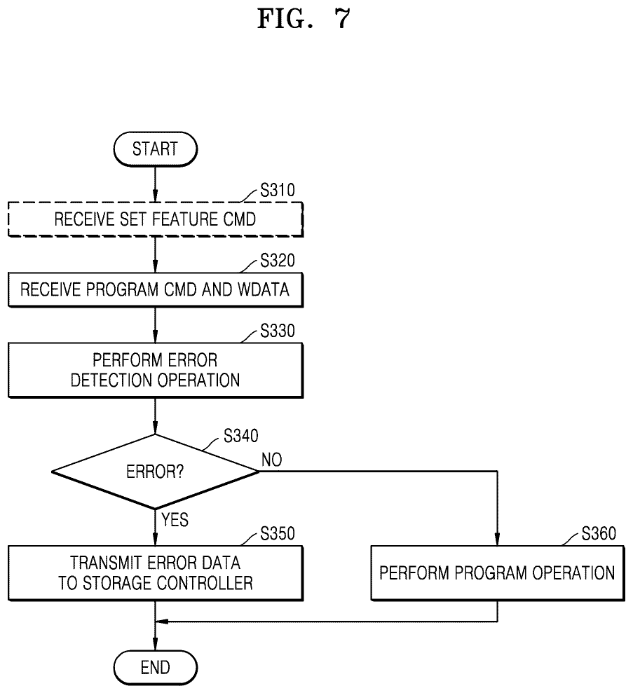

FIG. 7 is a flowchart illustrating an operating method of a nonvolatile memory device, according to an embodiment.

Referring to FIGS. 1, 2, and 7, in operation S310, the nonvolatile memory device 130 may receive a set-feature command. The nonvolatile memory device 130 may receive, from the storage controller 120, a set-feature command including error detection activation information. Operation S310 may be omitted. The nonvolatile memory device 130 may not perform operation S310.

For example, the storage controller 120 may transmit one set-feature command, and in a case in which an error of error data is not corrected, may transmit a plurality of program commands. That is, the nonvolatile memory device 130 may receive one set-feature command and may receive a plurality of program commands. Accordingly, in a case in which the nonvolatile memory device 130 has already received a set-feature command including error detection activation information, the nonvolatile memory device 130 may not receive a set-feature command again. However, the disclosure is not limited thereto, and as such, according to another embodiment, a set-feature command may be transmitted again corresponding to each of the plurality of program commands.

In operation S320, the nonvolatile memory device 130 may receive a program command and write data. The program command may include an address corresponding to an SLC area but the inventive concept is not limited thereto. The program command may include an address corresponding to an MLC area.

In operation S330, the nonvolatile memory device 130 may perform an error detection operation. The nonvolatile memory device 130 may detect an error occurring before a program operation. The nonvolatile memory device 130 may check in advance an error existing in data to be programmed. The nonvolatile memory device 130 may determine whether data is damaged by verifying the write data of the page buffer circuit 130 before programming the data to memory cells.

In operation S340, the nonvolatile memory device 130 may determine whether the write data includes an error. In a case in which the write data includes an error, the nonvolatile memory device 130 performs operation S350, and in a case in which the write data does not include an error, the nonvolatile memory device 130 performs operation S360.

In operation S350, the nonvolatile memory device 130 may transmit error data to the storage controller 120. The nonvolatile memory device 130 may output the write data as error data to a data line.

In operation S360, the nonvolatile memory device 130 may perform a program operation. Because the write data does not include an error, the nonvolatile memory device 130 may program the write data to the memory cell array 131. The nonvolatile memory device 130 may write the write data of the page buffer circuit 133 to the memory cells.

As described above, the nonvolatile memory device 130 may perform an error detection operation before programming write data of the page buffer circuit 133 to a memory cell. The nonvolatile memory device 130 may determine whether the write data is damaged by performing the error detection operation. The nonvolatile memory device 130 may enhance data integrity by performing the error detection operation.

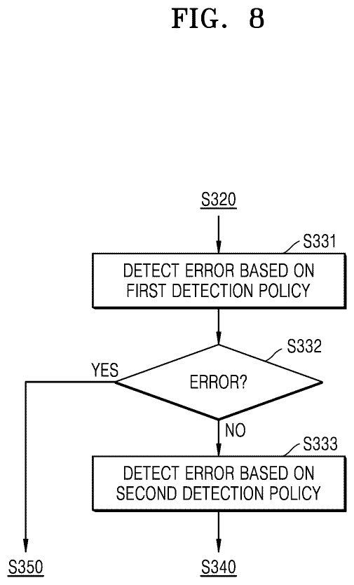

FIG. 8 is a flowchart illustrating operation S330 of FIG. 7 according to an embodiment.

Referring to FIGS. 1, 7, and 8, operation S330 of FIG. 7 may include operations S331 to S333 of FIG. 8. The nonvolatile memory device 130 may perform an error detection operation, before writing data to a memory cell array, in response to a program command. The nonvolatile memory device 130 may perform an error detection operation based on a plurality of detection policies.

In an embodiment, the nonvolatile memory device 130 may perform an error detection operation by using a plurality of detection policies in response to various error patterns. For example, a first detection policy may correspond to a first error pattern, and a second detection policy may correspond to a second error pattern. The first detection policy may be a policy for detecting the first error pattern. The second detection policy may be a policy for detecting the second error pattern.

In operation S331, the nonvolatile memory device 130 may detect an error in write data based on the first detection policy. To detect the first error pattern, the nonvolatile memory device 130 may detect an error in the write data by using the first detection policy.

In operation S332, the nonvolatile memory device 130 may determine whether an error in the write data is detected. The nonvolatile memory device 130 may determine whether an error in the write data is detected based on the first detection policy. In a case in which an error is detected, the nonvolatile memory device 130 performs operation S350, and in a case in which an error is not detected, the nonvolatile memory device 130 performs operations S333.

In a case in which the nonvolatile memory device 130 detects an error based on the first detection policy, the nonvolatile memory device 130 may transmit the write data to the storage controller 120. Because the nonvolatile memory device 130 detects the error, the nonvolatile memory device 130 may not use another detection policy.

In operation S333, the nonvolatile memory device 130 may detect an error in the write data based on the second detection policy. To detect the second error pattern, the nonvolatile memory device 130 may detect an error in the write data by using the second detection policy. Next, the nonvolatile memory device 130 performs operation S340.

As described above, the nonvolatile memory device 130 may perform an error detection operation based on a plurality of detection policies. Accordingly, the nonvolatile memory device 130 may detect errors of various patterns.

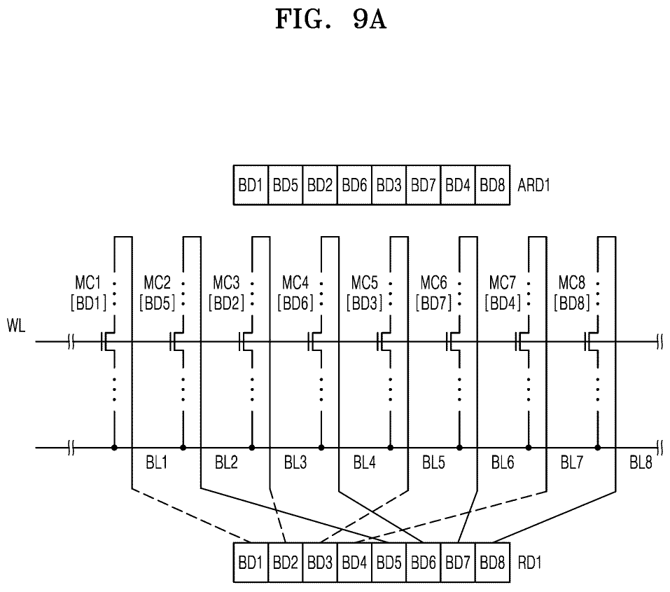

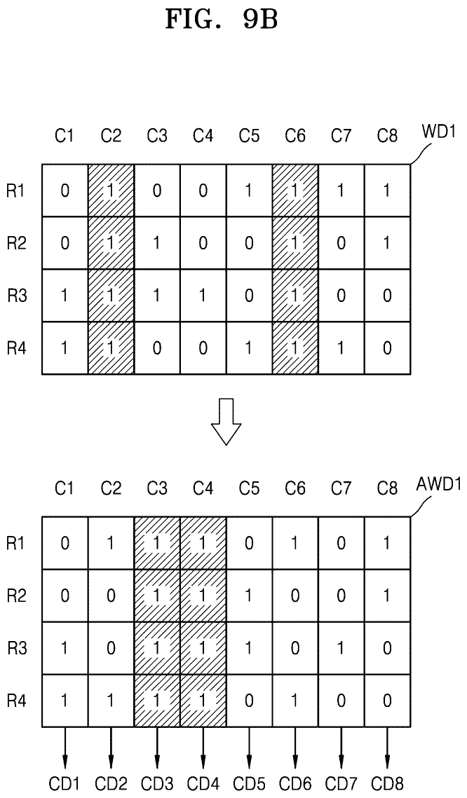

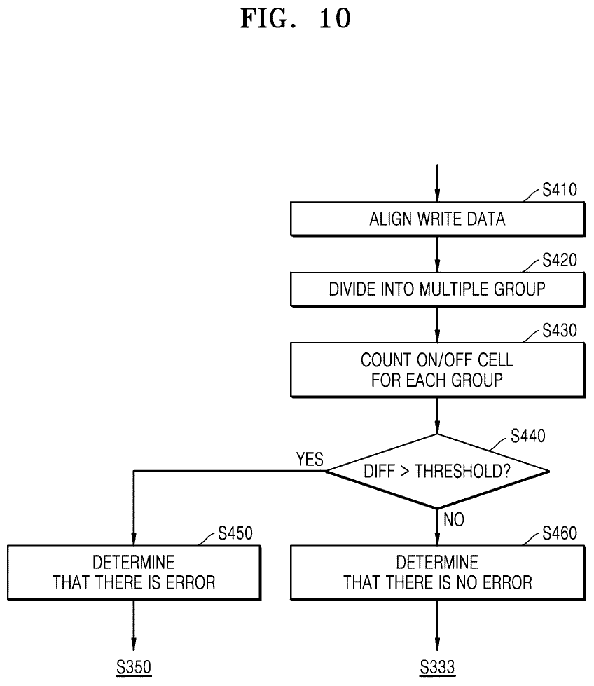

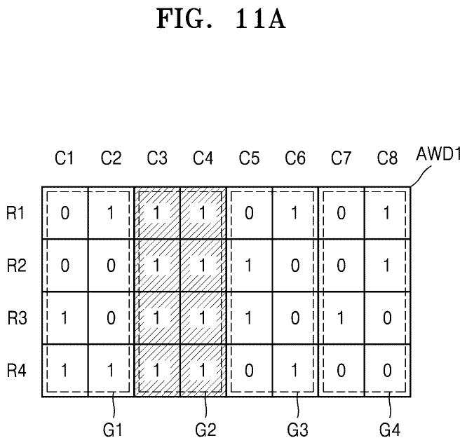

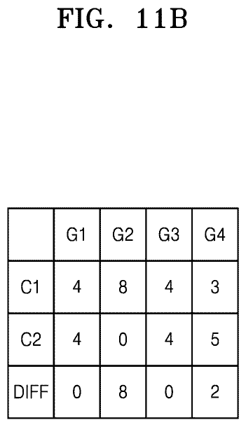

FIGS. 9A and 9B are diagrams for describing an operation of a nonvolatile memory device, according to an embodiment. FIG. 10 is a flowchart illustrating operation S331 of FIG. 8. FIGS. 11A and 11B are diagrams for describing an operation of a nonvolatile memory device, according to an embodiment.

Referring to FIGS. 8, 9A, 9B, 10, 11A and 11B, operation S331 of FIG. 8 may include operations S410 to S430, and operation S332 may include operations S440 to S460. In operation S410, the nonvolatile memory device 130 may align write data. In an embodiment, the error detection circuit 138 may re-align the write data of the page buffer circuit 133. The error detection circuit 138 may align the write data based on a physical column address.

In FIG. 9A, a method of programming data located in a first row R1 of FIG. 4A (i.e., first row data RD1) to the memory cell array 131 will be described. The first row data RD1 of first write data WD1 may include first to eighth bit data BD1 to BD8. The memory cell array 131 may include first to eighth memory cells MC1 to MC8. The first to eighth memory cells MC1 to MC8 may be connected to a word line WL. The first memory cell MC1 may be connected to a first bit line BL1, the second memory cell MC2 may be connected to a second bit line BL2, the third memory cell MC3 may be connected to a third bit line BL3, the fourth memory cell MC4 may be connected to a fourth bit line BL4, the fifth memory cell MC5 may be connected to a fifth bit line BL5, the sixth memory cell MC6 may be connected to a sixth bit line BL6, the seventh memory cell MC7 may be connected to a seventh bit line BL7, and the eighth memory cell MC8 may be connected to an eighth bit line BL8.

In an embodiment, the host device 10 may transmit the first write data WD1 aligned based on a logical address to the storage device 110. The storage controller 120 may transmit the first write data WD1 to the nonvolatile memory device 130. The page buffer circuit 133 may store the first write data WD1. The first row data RD1 of the first write data WD1 may be configured based on a logical address. That is, in the first write data WD1, the first to eighth bit data BD1 to BD8 may be arranged based on a logical address.

However, the first to eighth bit data BD1 to BD8 may not be stored in the first to eighth memory cells MC1 to MC8 based on a logical address (or sequentially). The first bit data BD1 may be stored in the first memory cell MC1, the fifth bit data BD5 may be stored in the second memory cell MC2, the second bit data BD2 may be stored in the third memory cell MC3, the sixth bit data BD6 may be stored in the fourth memory cell MC4, the third bit data BD3 may be stored in the fifth memory cell MC5, the seventh bit data BD7 may be stored in the sixth memory cell MC6, the fourth bit data BD4 may be stored in the seventh memory cell MC7, and the eighth bit data BD8 may be stored in the eighth memory cell MC8. As such adjacent bit data in write data may not be stored in adjacent memory cells.

For example, in a case in which the first to eighth bit data BD1 to BD8 are aligned in the order of being stored in the memory cells (i.e., referring to first aligned row data ARD1), a first column C1 may be the first bit data BD1, a second column C2 may be the fifth bit data BD5, a third column C3 may be the second bit data BD2, a fourth column C4 may be the sixth bit data BD6, a fifth column C5 may be the third bit data BD3, a sixth column C6 may be the seventh bit data BD7, a seventh column C7 may be the fourth bit data BD4, and an eighth column C8 may be the eighth bit data BD8.

In FIG. 9B, the first write data WD1 and first aligned write data AWD1 will be described. The first write data WD1 has been described with reference to FIG. 4A, and thus, a detailed description thereof will be omitted. The error detection circuit 138 may generate the first aligned write data AWD1 based on the first write data WD1. First column data CD1 of the first aligned write data AWD1 may be ‘0011’, second column data CD2 may be ‘1001’, third column data CD3 may be ‘1111’, fourth column data CD4 may be ‘1111’, fifth column data CD5 may be ‘0110’, sixth column data CD6 may be ‘1001’, seventh column data CD7 may be ‘0010’, and eighth column data CD8 may be ‘1100’.

The error detection circuit 138 may determine whether a specific pattern repeats based on aligned write data. For example, the error detection circuit 138 may determine whether there is an error by determining whether all of a plurality of pieces of adjacent column data of write data have the same value. An error may occur in the third column data CD3 and the fourth column data CD4 of the first aligned write data AWD1.

In operation S420, the error detection circuit 138 may divide the aligned write data into a plurality of groups. For example, the error detection circuit 138 may divide the first aligned write data AWD1 into a first group G1, a second group G2, a third group G3 and a fourth group G4. As shown in FIG. 11A, the first group G1 may include the first column data CD1 and the second column data CD2, the second group G2 may include the third column data CD3 and the fourth column data CD4, the third group G3 may include the fifth column data CD5 and the sixth column data CD6, and the fourth group G4 may include the seventh column data CD7 and the eighth column data CD8.

In operation S430, the error detection circuit 138 may count an on/off cell of each group. For example, in a case in which an off cell of the write data is counted, it may mean the number of bit data having a first value (e.g., ‘1’) is counted, and in a case in which an on cell of the write data is counted, it may mean that the number of bit data having a second value (e.g., ‘0’) is counted. However, the disclosure is not limited thereto, and as such, according to another embodiment, the first value (e.g., ‘1’) may be counted as an on cell of the write data and the second value (e.g., ‘0’) may be counted as an off cell of the write data.

In an embodiment, the error detection circuit 138 may count the first value (e.g., ‘1’) in the write data or the aligned write data as a first count C1. The error detection circuit 138 may count the second value (e.g., ‘0’) in the write data or the aligned write data as a second count C2. For example, as shown in FIG. 11B, in the first aligned write data AWD1, the first count C1 of the first group G1 may be ‘4’ and the second count C2 of the first group G1 may be ‘4’. In the first aligned write data AWD1, the first count C1 of the second group G2 may be ‘8’ and the second count C2 of the second group G2 may be ‘0’. In the first aligned write data AWD1, the first count C1 of the third group G3 may be ‘4’ and the second count C2 of the third group G3 may be ‘4’. In the first aligned write data AWD1, the first count C1 of the fourth group G4 may be ‘3’ and the second count C2 of the fourth group G4 may be ‘5’.

In operation S440, the nonvolatile memory device 130 may determine whether a difference DIFF is greater than a threshold value. The threshold value may be a pre-determined value. For example, the difference DIFF may be an absolute value of a difference between the first count C1 and the second count C2. For example, the difference DIFF may be obtained by subtracting the first count C1 from the second count C2 or by subtracting the second count C2 from the first count C1. In an embodiment, the error detection circuit 138 may compare a difference of on/off cells with a threshold value. For example, the error detection circuit 138 may compare a difference between the first count C1 and the second count C2 with a threshold value. In a case in which the difference DIFF is greater than the threshold value, the nonvolatile memory device 130 performs operation S450, and in a case in which the difference DIFF is equal to or less than the threshold value, the nonvolatile memory device 130 performs operation S460.

For example, the error detection circuit 138 may compare the difference DIFF with the threshold value for each group. The error detection circuit 138 may calculate a difference for each group. The error detection circuit 138 may calculate the difference DIFF based on the first count C1 and the second count C2. In the first aligned write data AWD1, the difference DIFF of the first group G1 may be ‘0’, the difference DIFF of the second group G2 may be ‘8’, the difference DIFF of the third group G3 may be ‘0’, and the difference DIFF of the fourth group G4 may be ‘2’.

In operation S450, the nonvolatile memory device 130 may determine that there is an error in the write data. In a case in which the difference between the first count C1 and the second count C2 is greater than the threshold value, the error detection circuit 138 may determine that an error has occurred. Next, the nonvolatile memory device 130 performs operation S350. For example, based on a determination that the write data includes an error, the nonvolatile memory device 130 may transmit the write data to the storage controller 120.

In operation S460, the nonvolatile memory device 130 may determine that there is no error in the write data. In a case in which the difference between the first count C1 and the second count C2 is equal to or less than the threshold value, the error detection circuit 138 may determine that an error has not occurred. Next, the nonvolatile memory device 130 performs operation S333. For example, based on a determination that the write data does not include an error, the nonvolatile memory device 130 may detect an error based on a second detection policy. That is, in a case in which the nonvolatile memory device 130 has failed to detect an error based on the first detection policy, the nonvolatile memory device 130 may detect an error by using the second detection policy different from the first detection policy. However, the disclosure is not limited thereto, and as such, according to another embodiment, an error detect based on the second detection policy may not be performed.

In an example case in which the threshold value is ‘7’, the error detection circuit 138 may determine that the difference DIFF (‘0’) of the first group G1 is equal to or less than the threshold value. That is, the error detection circuit 138 may determine that there is no error in the first group G1. According to another embodiment, the threshold value may be different than ‘7’. Regarding the second group G2, the error detection circuit 138 may determine that the difference DIFF (‘8’) of the second group G2 is greater than the threshold value. That is, the error detection circuit 138 may determine that there is an error in the second group G2. Regarding third group G3, the error detection circuit 138 may determine that the difference DIFF (‘0’) is equal to or less than the threshold value. That is, the error detection circuit 138 may determine that there is no error in the third group G3. Regarding the fourth group G4, the error detection circuit 138 may determine that the difference DIFF (‘2’) is equal to or less than the threshold value. That is, the error detection circuit 138 may determine that there is no error in the fourth group G4. Because the error detection circuit 138 determines that an error has occurred in the second group G2 from among the plurality of groups G1 to G4, the error detection circuit 138 may transmit the first write data WD1 as error data to the storage controller 120.

As described above, the nonvolatile memory device 130 may align write data and may detect an error based on the aligned write data. The nonvolatile memory device 130 may detect an error by using an on/off cell count for the aligned write data. However, the inventive concept is not limited thereto. For example, the nonvolatile memory device 130 may count a first value in write data as a first count and may count a second value in the write data as a second count. The nonvolatile memory device 130 may determine whether a difference between the first count and the second count is greater than a threshold value. In a case in which the difference between the first count and the second count is greater than the threshold value, the nonvolatile memory device 130 may determine that an error has occurred. In a case in which the difference between the first count and the second count is equal to or less than the threshold value, the nonvolatile memory device 130 may determine that an error has not occurred. As such, the nonvolatile memory device 130 may detect an error by using an on/off cell count, for write data stored in a page buffer circuit and not aligned.

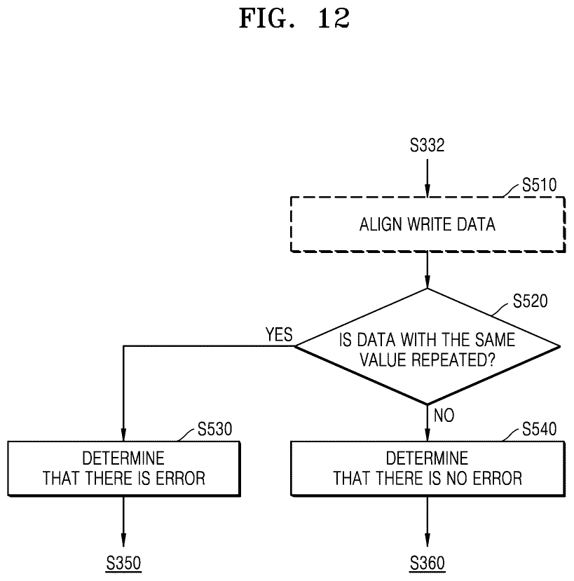

FIG. 12 is a flowchart illustrating the operation S333 of FIG. 8 according to an embodiment.

Referring to FIGS. 8 and 12, the operation S333 of FIG. 8 may include operations S510 to S540. However, the disclosure is not limited thereto, and as such, the operation S333 may include other operations or omit some of the operations. In operation S510, the nonvolatile memory device 130 may align write data. For example, the nonvolatile memory device 130 may align the write data based on a physical column address. In an embodiment, operation S510 may be omitted. In a case in which the write data is aligned in detecting an error based on a first detection policy, the error detection circuit 138 may not perform an operation of aligning the write data.

In operation S520, the nonvolatile memory device 130 may determine whether data having the same value repeats. For example, the error detection circuit 138 may determine whether data having the same value (e.g., 0X00 or 0XFF) repeats in units of physical columns in the aligned write data. In an embodiment, the error detection circuit 138 may determine whether data having the same value repeats in units of logical columns or units of specific multiples based on a logical address in the write data. The error detection circuit 138 may determine whether all pieces of column data of the write data or the aligned write data have the same value. In a case in which the nonvolatile memory device 130 determines that data having the same value repeats, the nonvolatile memory device 130 performs operation S530, and in a case in which the nonvolatile memory device 130 determines that data having the same value does not repeat, the nonvolatile memory device 130 performs operation S540.

In operation S530, the nonvolatile memory device 130 may determine that there is an error. The nonvolatile memory device 130 may determine that there is an error because data having the same value repeats in the write data (or the aligned write data). Next, the nonvolatile memory device 130 performs operation S350. That is, the nonvolatile memory device 130 may transmit error data to the storage controller 120.

In operation S540, the nonvolatile memory device 130 may determine that there is no error. The nonvolatile memory device 130 may determine that there is no error because data having the same value does not repeat in the write data (or the aligned write data). Next, the nonvolatile memory device 130 performs operation S360. That is, the nonvolatile memory device 130 may write the write data to the memory cell array 131.

As described above, the nonvolatile memory device 130 may detect an error in write data based on a second detection policy. In an embodiment, the nonvolatile memory device 130 may detect an error in aligned write data based on a second detection policy. The nonvolatile memory device 130 may determine whether all pieces of column data in write data or aligned write data have the same value.

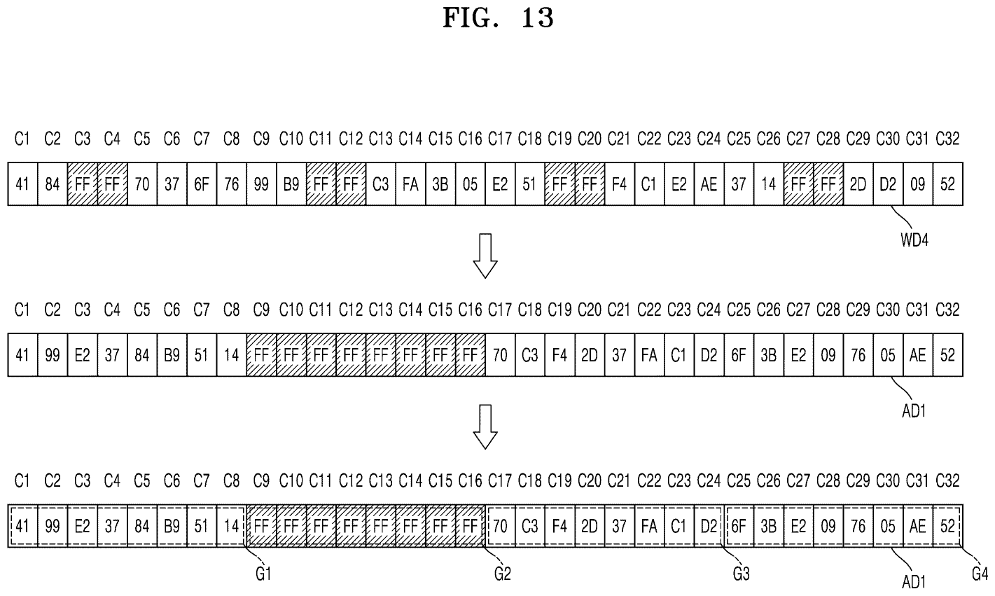

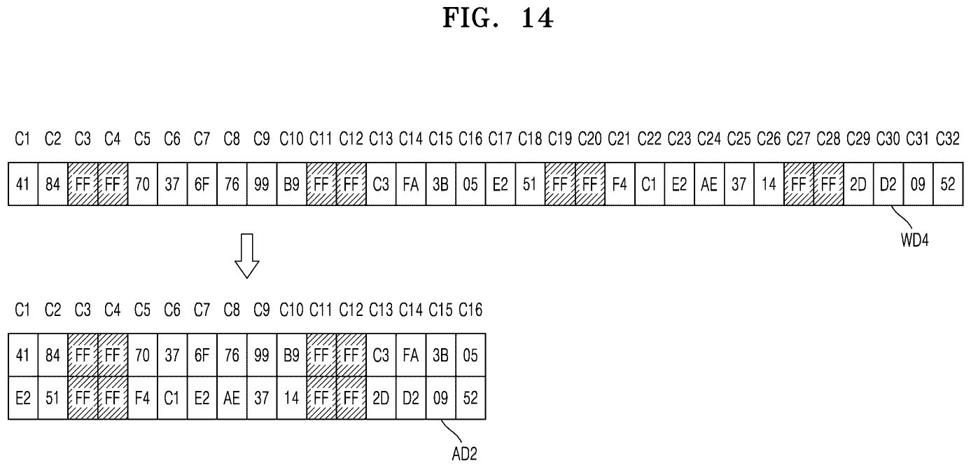

FIGS. 13 and 14 are diagrams for describing an operation of a nonvolatile memory device, according to an embodiment.

Referring to FIGS. 13 and 14, the nonvolatile memory device 130 may perform an error detection operation. The nonvolatile memory device 130 may detect an error in write data by using a first detection policy or a second detection policy. In an embodiment, the nonvolatile memory device 130 may detect an error in aligned write data through a plurality of detection policies.

In an embodiment, the error detection circuit 138 may align write data. The error detection circuit 138 may generate aligned data by aligning write data. For example, the write data may be data based on a logical address. In an embodiment, the error detection circuit 138 may align the write data based on a physical address. In an embodiment, the error detection circuit 138 may align the write data by dividing the write data into parts, and arranging the parts of the write data in a plurality of columns. However, the scope of the inventive concept is not limited thereto, and the error detection circuit 138 may align the write data in various ways.

Referring to FIG. 13, fourth write data WD4 may have a hexadecimal format and may be ‘32 bytes’. For example, the fourth write data WD4 may be ‘41 84 FF FF 70 37 6F 76 99 B9 FF FF C3 FA 3B 05 E2 51 FF FF F4 C1 E2 AE 37 14 FF FF 2D D2 09 52’. The fourth write data WD4 may include ‘1’ row and ‘32’ columns. The error detection circuit 138 may detect an error by using a first policy. For example, the error detection circuit 138 may align the fourth write data WD4. The error detection circuit 138 may generate first aligned data AD1 by aligning the fourth write data WD4.

The error detection circuit 138 may align write data aligned based on a logical address corresponding to a physical address. For example, the error detection circuit 138 may generate the first aligned data AD1 by aligning the fourth write data WD4 based on a physical address. For example, the first aligned data AD1 may be ‘41 99 E2 37 84 B9 51 14 FF FF FF FF FF FF FF FF 70 C3 F4 2D 37 FA C1 D2 6F 3B E2 09 76 05 AE 52’.

The error detection circuit 138 may divide the first aligned data AD1 into a plurality of groups. The error detection circuit 138 may divide data into a plurality of groups so that one group includes a pre-determined number of bit data. For example, the number of byte data included in one group may be ‘8’. That is, the error detection circuit 138 may divide the first aligned data AD1 into first to fourth groups G1 to G4. The first group G1 may include data of first to eighth columns C1 to C8, the second group G2 may include data of ninth to 16th columns C9 to C16, the third group G3 may include data of 17^{th} to 24^{th} columns C17 to C24, and the fourth group G4 may include data of 25^{th} to 32^{nd} columns C25 to C32.

The error detection circuit 138 may count an on/off cell for each of the plurality of groups. That is, the error detection circuit 138 may count first and second counts C1 and C2 for each of the plurality of groups. The error detection circuit 138 may compare a difference between an on cell and an off cell with a first threshold value. That is, the error detection circuit 138 may calculate a difference DIFF for each group based on the first and second counts C1 and C2. The error detection circuit 138 may compare the difference DIFF for each group with the first threshold value. For example, because the second group G2 is ‘FF FF FF FF FF FF FF FF’, the difference DIFF of the second group G2 may be greater than the first threshold value. The error detection circuit 138 may determine that an error has occurred.

In an embodiment, the error detection circuit 138 may detect an error by using a second detection policy. The error detection circuit 138 may determine whether data having the same value repeats. For example, the error detection circuit 138 may determine whether a specific pattern repeats in data. The error detection circuit 138 may determine whether the same value repeats in units of specific multiples in data. In an embodiment, the error detection circuit 138 may determine whether all pieces of consecutive column data have the same value in data.

In an embodiment, the error detection circuit 138 may determine that an error has occurred when data of columns equal to or greater than a second threshold value have the same value. In an example case, the second threshold value may be ‘4’. The error detection circuit 138 may determine whether data of consecutive columns have the same value based on a logical address. The error detection circuit 138 may determine whether data of columns equal to or greater than the second threshold value have the same value in the fourth write data WD4. Referring to FIG. 13, in the fourth write data WD4, because data of the third and fourth columns C3 and C4 are the same, data of the 11^{th} and 12^{th} columns C11 and C12 are the same, data of 19^{th} and 20^{th} columns C19 and C20 are the same, and data of 27^{th} to 28^{th} columns C27 and C28 are the same, but the columns are not consecutive columns equal to or greater than the second threshold value, it may be determined that there is no error.

The error detection circuit 138 may apply the second detection policy to the first aligned data AD1 aligned based on a physical address. The error detection circuit 138 may detect an error based on the first aligned data AD1. The error detection circuit 138 may determine whether data of columns equal to or greater than the second threshold value in the first aligned data AD1 have the same value. In the first aligned data AD1, because data of the ninth to 16^{th} columns C9 to C16 are the same and the columns are consecutive columns equal to or greater than the second threshold value, it may be determined that an error has occurred. As such, the error detection circuit 138 may not detect an error in data arranged based on a logical address, but may detect an error in aligned data arranged based on a physical address.

In an embodiment, the error detection circuit 138 may align write data by dividing the write data into parts and arranging the parts of the write data in a plurality of columns. The error detection circuit 138 may divide the write data in units of pre-determined bits or pre-determined bytes. The error detection circuit 138 may divide the write data and may align the data including a plurality of columns. That is, the error detection circuit 138 may divide the write data into parts in pre-determined units and may arrange the parts of the write data in a plurality of columns.

Referring to FIG. 14, the error detection circuit 138 may generate second aligned data AD2 by aligning the fourth write data WD4. For example, the second aligned data AD2 may include ‘2’ rows and ‘16’ columns. That is, first row data RD1 of the second aligned data AD2 may be ‘41 84 FF FF 70 37 6F 76 99 B9 FF FF C3 FA 3B 05’, and second row data RD2 of the first aligned data AD1 may be ‘E2 51 FF FF F4 C1 E2 AE 37 14 FF FF 2D D2 09 52’. For example, the error detection circuit 138 may divide the fourth write data WD4 in units of ‘16 bytes’. The error detection circuit 138 may divide the fourth write data WD4 in units of ‘16 bytes’ and may align the fourth write data WD4 into data including a plurality of columns.

For example, the error detection circuit 138 may determine whether data of consecutive columns have the same value in both the first row data RD1 and the second row data RD2. The error detection circuit 138 may determine whether consecutive column data have the same value. Because data of the consecutive third and fourth columns C3 and C4 have a third value (e.g., ‘FF’) and data of the consecutive 11^{th} and 12^{th} columns C11 and C12 have the third value (e.g., ‘FF’), the error detection circuit 138 may determine that an error has occurred.

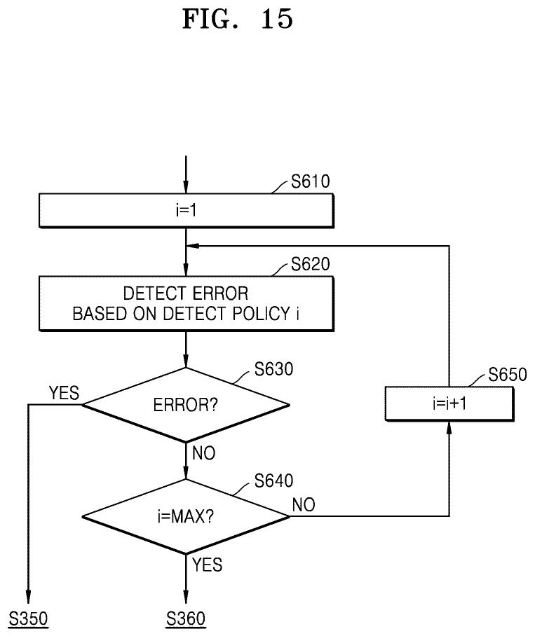

FIG. 15 is a flowchart illustrating operation S330 of FIG. 7 according to another embodiment.

Referring to FIGS. 7 and 15, operation S330 of FIG. 7 may include operations S610 to S650. In an embodiment, the nonvolatile memory device 130 may use a plurality of detection policies to detect errors of various patterns. The nonvolatile memory device 130 may perform an error detection operation by using a plurality of detection policies.

In operation S610, a variable i may be set to 1. For example, the variable i is used to describe an operation of repeatedly performing an error detection operation by using a plurality of detection policies of the nonvolatile memory device 130, and does not limit the scope of the inventive concept.

In operation S620, the nonvolatile memory device 130 may detect an error based on an i^{th} detection policy. The nonvolatile memory device 130 may detect an error pattern corresponding to the i^{th} detection policy. In operation S630, the nonvolatile memory device 130 may determine whether an error has occurred in write data. The nonvolatile memory device 130 may perform operation S350 when an error is detected. That is, in a case in which an error is detected, the nonvolatile memory device 130 may transmit error data to the storage controller 120. In a case in which an error is not detected, the nonvolatile memory device 130 may perform operation S640.

In operation S640, the nonvolatile memory device 130 may determine whether the variable i is a maximum value. The maximum value may be a pre-determined value. The maximum value may indicate the number of detection policies. In a case in which the variable i is the maximum value, the nonvolatile memory device 130 may perform operation S360. That is, the nonvolatile memory device 130 may write the write data to the memory cell array 131. In a case in which the variable i is not the maximum value, the nonvolatile memory device 130 performs operation S650. In operation S650, the nonvolatile memory device 130 may increase the variable i by 1. Next, the nonvolatile memory device 130 may perform operation S620. Because the nonvolatile memory device 130 has failed to detect an error, the nonvolatile memory device 130 may detect an error by using another detection policy.

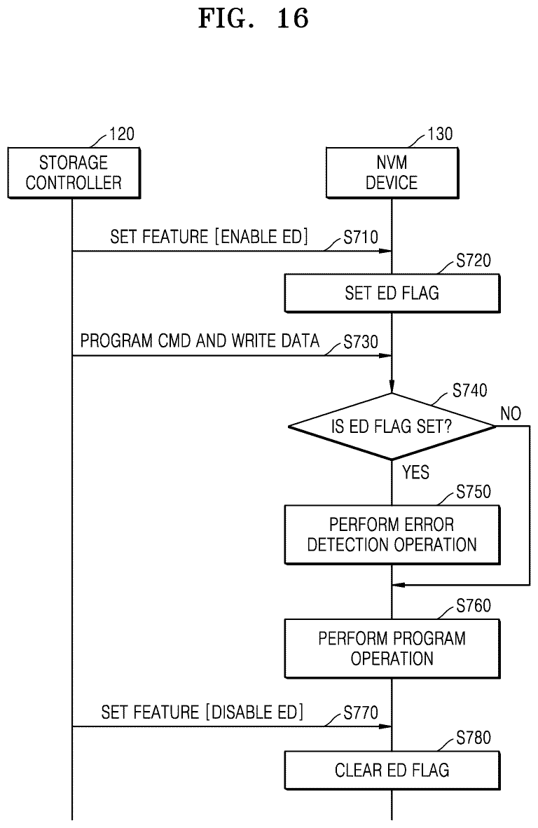

FIG. 16 is a flowchart illustrating an operating method of a storage device, according to an embodiment.

In operation S710, the storage controller 120 may transmit a set-feature command including error detection activation information to the nonvolatile memory device 130. The nonvolatile memory device 130 may receive the set-feature command. In operation S720, the nonvolatile memory device 130 may set an error detection (ED) flag. The nonvolatile memory device 130 may set an error detection flag based on the set-feature command including the error detection activation information. For example, in response to receiving the set-feature command including the error detection activation information, the nonvolatile memory device 130 may set the error detection flag.

In an embodiment, the error detection flag may be a flag indicating whether the nonvolatile memory device 130 is to perform an error detection operation when a program command is received. For example, in a case in which the error detection flag is set, the nonvolatile memory device 130 may perform an error detection operation before writing data to the memory cell array 131 upon receiving a program command. In a case in which the error detection flag is cleared, the nonvolatile memory device 130 may write data to the memory cell array 131 without performing an error detection operation upon receiving a program command.

In operation S730, the storage controller 120 may transmit a program command and write data. The nonvolatile memory device 130 may receive the program command and the write data. In operation S740, the nonvolatile memory device 130 may determine whether the error detection flag is set. In a case in which the error detection flag is set, the nonvolatile memory device 130 performs operation S750, and in a case in which the error detection flag is not set, the nonvolatile memory device 130 performs operation S760.

In operation S750, the nonvolatile memory device 130 may perform an error detection operation. For example, the nonvolatile memory device 130 may transmit the write data of the page buffer circuit 133 to the storage controller 120 when an error is detected. In operation S760, the nonvolatile memory device 130 may perform a program operation. The nonvolatile memory device 130 may program the write data to memory cells.

In operation S770, the storage controller 120 may transmit a set-feature command including error detection deactivation information to the nonvolatile memory device 130. When programming of data for which high reliability is required is completed, the storage controller 120 may request the nonvolatile memory device 130 not to perform an error detection operation for a subsequent program command. For general user data other than metadata, the storage controller 120 may request the nonvolatile memory device 130 to program the data without an error detection operation. However, the disclosure is not limited thereto, and as such, the storage controller 120 may request the nonvolatile memory device 130 to perform the error detection operation on various types of data.

In operation S780, the nonvolatile memory device 130 may clear the error detection flag. For example, the nonvolatile memory device 130 may receive the set-feature command including the error detection deactivation information. The nonvolatile memory device 130 may clear the error detection flag in response to the set-feature command including the error detection deactivation information.

As described above, after a program command is completed, the storage controller 120 may transmit a set-feature command including error detection deactivation information to the nonvolatile memory device 130. The storage controller 120 may activate or deactivate error detection of the nonvolatile memory device 130 by using a set-feature command. The nonvolatile memory device 130 may not perform an error detection operation on data for which high reliability is not required. Accordingly, the storage device 110 may reduce write latency.

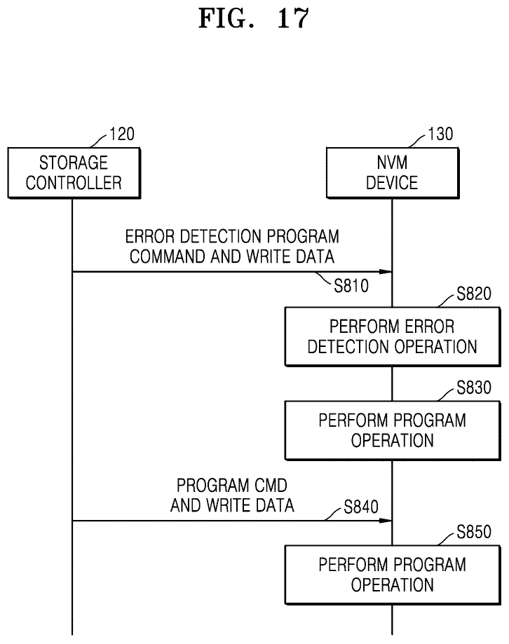

FIG. 17 is a flowchart illustrating an operating method of a storage device, according to an embodiment.

In operation S810, the storage controller 120 may transmit an error detection program command and write data to the nonvolatile memory device 130. For example, the error detection program command may be different from a general program command. For example, the error detection program command may be a vendor command. The error detection program command may be a command for requesting both an error detection operation and a program operation.

In operation S820, the nonvolatile memory device 130 may perform an error detection operation. For example, the nonvolatile memory device 130 may perform an error detection operation in response to the error detection program command. In a case in which an error is detected in the write data, the nonvolatile memory device 130 may transmit the write data as error data to the storage controller 120. In operation S830, the nonvolatile memory device 130 may perform a program operation. The nonvolatile memory device 130 may program the write data to memory cells.

In operation S840, the storage controller 120 may transmit a program command and write data to the nonvolatile memory device 130. In operation S850, the nonvolatile memory device 130 may perform a program operation. For example, the nonvolatile memory device 130 may receive the program command. The nonvolatile memory device 130 may directly perform a program operation without performing an error detection operation, in response to the program command.

As described above, the storage controller 120 may request the nonvolatile memory device 130 to perform an error detection operation through a vendor command other than a set-feature command.

While the inventive concept has been particularly shown and described with reference to embodiments thereof, it will be understood that various changes in form and details may be made therein without departing from the spirit and scope of the following claims.

What is claimed is:

1. An operating method of a storage device including a nonvolatile memory device and a storage controller, the operating method comprising:
transmitting, by the storage controller, error detection activation information to the nonvolatile memory device;
transmitting, by the storage controller, a program command and write data to the nonvolatile memory device;
performing, by the nonvolatile memory device, an error detection operation on the write data in a page buffer circuit based on the error detection activation information;
transmitting, by the nonvolatile memory device, the write data as error data to the storage controller based on an error being detected in the write data; and
programming, by the nonvolatile memory device, the write data to memory cells in the nonvolatile memory device based on an error not being detected in the write data.

2. The operating method of claim 1, wherein the performing of the error detection operation comprises detecting whether a same pattern repeats in the write data.

3. The operating method of claim 1, wherein the program command comprises an address indicating an area of the memory cells in the nonvolatile memory device storing 1-bit data.

4. The operating method of claim 1, further comprising:
performing, by the storage controller, one of:
an error correction operation on the error data based on the error data, and an input/output adjustment operation based on the error data being an uncorrectable error; and
transmitting, by the storage controller, a resume command to program the write data based on the error being corrected.

5. The operating method of claim 4, wherein the performing of the input/output adjustment operation comprises adjusting a power supply voltage or an input/output voltage input to the nonvolatile memory device.

6. The operating method of claim 4, further comprising:
determining, by the storage controller, whether a program count, which is a number of times a program command is transmitted for a same address, is equal to or greater than a threshold value after performing the input/output adjustment operation;
based on a determination that the program count is equal to or greater than the threshold value, determining, by the storage controller, a program failure and storing information about the program failure; and
based on a determination that the program count is less than the threshold value, retransmitting, by the storage controller, the program command and the write data to the nonvolatile memory device.

7. The operating method of claim 1, wherein the performing of the error detection operation comprises:
performing a first error detection operation based on a first policy to determine whether an error has occurred in the write data; and
based on an error not being detected in the write data based on the first policy, performing a second error detection operation based on a second policy to determine whether an error has occurred in the write data, the second policy being different from the first policy.

8. The operating method of claim 7, wherein the first error detection operation comprises:
counting a first value in the write data as a first count and counting a second value in the write data as a second count; determining whether a difference between the first count and the second count is greater than a threshold value;
determining that the error has occurred in the write data based on the difference between the first count and the second count being greater than the threshold value; and
determining that the error has not occurred based on the difference between the first count and the second count being equal to or less than the threshold value.

9. The operating method of claim 7, wherein the first error detection operation comprises:
aligning the write data based on a physical column address;
dividing the aligned write data into a plurality of groups; and
counting a first value in each of the plurality of groups as a first count and counting a second value in each of the plurality of groups as a second count, and
determining, for the plurality of groups, whether a difference between the first count and the second count for each of the plurality of groups is greater than a threshold value;
determining that the error has occurred based on the difference between the first count and the second count in one or more of the plurality of groups being greater than the threshold value; and
determining that the error has not occurred based on the difference between the first count and the second count for each of the plurality of groups being equal to or less than the threshold value.

10. The operating method of claim 7, wherein the second error detection operation comprises determining whether all pieces of consecutive column data in the write data have a same value.

11. The operating method of claim 7, wherein the second error detection operation comprises:
aligning the write data based on a physical column address; and
determining whether all pieces of consecutive column data in the aligned write data have a same value.

12. The operating method of claim 1, further comprising transmitting, by the storage controller, error detection deactivation information to the nonvolatile memory device after the program command is completed.

13. An operating method of a nonvolatile memory device, the operating method comprising:
receiving error detection activation information from a storage controller;
receiving a program command and write data from the storage controller;
performing, based on error detection activation information, an error detection operation by detecting whether a same pattern repeats in the write data of a page buffer circuit;
based on an error being detected in the write data, transmitting the write data as error data to the storage controller; and
based on an error being not detected in the write data, programming the write data to memory cells in nonvolatile memory device.

14. The operating method of claim 13, wherein the receiving of the program command and the write data from the storage controller comprises receiving a program command comprising an address indicating an area of the memory cells in the nonvolatile memory device storing 1-bit data.

15. The operating method of claim 13, wherein the performing of the error detection operation comprises:
counting a first value in the write data as a first count and counting a second value in the write data as a second count;
determining whether a difference between the first count and the second count is greater than a threshold value;
determining that the error has occurred in the write data based on the difference between the first count and the second count being greater than the threshold value; and
determining that the error has not occurred in the write data based on the difference between the first count and the second count being equal to or less than the threshold value.

16. The operating method of claim 13, wherein the performing of the error detection operation comprises:
aligning the write data based on a physical column address;
dividing the aligned write data into a plurality of groups;
counting a first value in each of the plurality of groups as a first count and counting a second value in each of the plurality of groups as a second count;
determining, for the plurality of groups, whether a difference between the first count and the second count for each of the plurality of groups is greater than a threshold value;
determining that the error has occurred based on the difference between the first count and the second count in one or more of the plurality of groups being greater than the threshold value; and
determining that the error has not occurred based on the difference between the first count and the second count for each of the plurality of groups being equal to or less than the threshold value.

17. The operating method of claim 13, wherein the performing of the error detection operation comprises determining whether all pieces of consecutive column data in the write data have a same value.

18. A nonvolatile memory device comprising:
a memory cell array comprising a plurality of memory cells;
an input/output circuit configured to receive write data from a storage controller;
a page buffer circuit connected to the memory cell array and configured to temporarily store the write data from the input/output circuit; and
an error detection circuit configured to:
receive error detection activation information from the storage controller,
perform, based on error detection activation information, an error detection operation by detecting whether a same pattern in the write data repeats before programming the write data to the memory cell array,
based on an error being detected in the write data, transmit the write data as error data to the storage controller, and
based on an error being not detected in the write data, program the write data to the memory cells.

19. The nonvolatile memory device of claim 18, wherein the error detection circuit is further configured to:
count a first value in the write data as a first count and count a second value in the write data as a second count,
determine whether a difference between the first count and the second count is greater than a threshold value,
determine that the error has occurred based on the difference between the first count and the second count being greater than the threshold value, and
determine that the error has not occurred based on the difference between the first count and the second count being equal to or less than the threshold value.

20. The nonvolatile memory device of claim 18, wherein the error detection circuit is further configured to:
align the write data based on a physical column address,
divide the aligned write data into a plurality of groups,
count a first value in each of the plurality of groups as a first count and count a second value in each of the plurality of groups as a second count,
determine, for the plurality of groups, whether a difference between the first count and the second count is greater than a threshold value,
determine that the error has occurred based on the difference between the first count and the second count in one or more of the plurality of groups being greater than the threshold value, and
determine that the error has not occurred based on the difference between the first count and the second count for each of the plurality of groups being equal to or less than the threshold value.
